(19) United States
(12) Patent Application Publication
(10) Pub. No.: US 2007/0297247 A1
(43) Pub. Date: Dec. 27, 2007

(54) METHOD FOR PROGRAMMING NON-VOLATILE MEMORY USING VARIABLE AMPLITUDE PROGRAMMING PULSES

(76) Inventor: Gerrit Jan Hemink, Yokohama (JP)

Correspondence Address: VIERRA MAGEN/SANDISK CORPORATION, 575 MARKET STREET, SUITE 2500, SAN FRANCISCO, CA, 94105, US

(21) Appl. No.: 11/426,475

(22) Filed: Jun. 26, 2006

(51) Int. Cl. G11C 16/04; G11C 7/00; G11C 11/34

(52) U.S. Cl. 365/185.33; 365/195

(57) ABSTRACT

Non-volatile storage elements are programmed using a series of voltage waveforms, where each waveform includes different portions with different amplitudes. For example, the amplitudes can vary as a decreasing staircase or ramp. Storage elements which are to be programmed to the highest level are programmed using the entire waveform, while storage elements which are to be programmed to intermediate and lower levels are programmed using different portions of the waveform. For example, the storage elements to be programmed to the intermediate level are programmed using the last two-thirds of each waveform, while the storage elements to be programmed to the lower level are programmed using the last one-third of each waveform. For these storage elements, programming is inhibited for a portion of the waveform by applying an inhibit voltage to an associated bit line. Higher programming speeds and narrower threshold voltage distributions can be achieved.

### BACKGROUND OF THE INVENTION

1. Field of the Invention

The present invention relates to non-volatile memory.

2. Description of the Related Art

Semiconductor memory has become increasingly popular for use in various electronic devices. For example, non-volatile semiconductor memory is used in cellular telephones, digital cameras, personal digital assistants, mobile computing devices, non-mobile computing devices and other devices. Electrically Erasable Programmable Read Only Memory (EEPROM) and flash memory are among the most popular non-volatile semiconductor memories. With flash memory, also a type of EEPROM, the contents of the whole memory array, or of a portion of the memory, can be erased in one step, in contrast to the traditional, full-featured EEPROM.

Both the traditional EEPROM and the flash memory utilize a floating gate that is positioned above and insulated from a channel region in a semiconductor substrate. The floating gate is positioned between the source and drain regions. A control gate is provided over and insulated from the floating gate. The threshold voltage (Vt) of the transistor thus formed is controlled by the amount of charge that is retained on the floating gate. That is, the minimum amount of voltage that must be applied to the control gate before the transistor is turned on to permit conduction between its source and drain is controlled by the level of charge on the floating gate.

Some EEPROM and flash memory devices have a floating gate that is used to store two ranges of charges and, therefore, the memory element can be programmed/erased between two states, e.g., an erased state and a programmed state. Such a flash memory device is sometimes referred to as a binary flash memory device because each memory element can store one bit of data.

A multi-state (also called multi-level) flash memory device is implemented by identifying multiple distinct allowed/valid programmed threshold voltage ranges. Each distinct threshold voltage range corresponds to a predetermined value for the set of data bits encoded in the memory device. For example, each memory element can store two bits of data when the element can be placed in one of four discrete charge bands corresponding to four distinct threshold voltage ranges.

Typically, a program voltage Vpgm applied to the control gate during a program operation is applied as a series of pulses that increase in magnitude over time. In one possible approach, the magnitude of the pulses is increased with each successive pulse by a predetermined step size, e.g., 0.2-0.4 V. Vpgm can be applied to the control gates of flash memory elements. In the periods between the program pulses, verify operations are carried out. That is, the programming level of each element of a group of elements being programmed in parallel is read between successive programming pulses to determine whether it is equal to or greater than a verify level to which the element is being programmed. For arrays of multi-state flash memory elements, a verification step may be performed for each state of an element to determine whether the element has reached its data-associated verify level. For example, a multi-state memory element capable of storing data in four states may need to perform verify operations for three compare points.

Moreover, when programming an EEPROM or flash memory device, such as a NAND flash memory device in a NAND string, typically Vpgm is applied to the control gate and the bit line is grounded, causing electrons from the channel of a cell or memory element, e.g., storage element, to be injected into the floating gate. When electrons accumulate in the floating gate, the floating gate becomes negatively charged and the threshold voltage of the memory element is raised so that the memory element is considered to be in a programmed state. More information about such programming can be found in U.S. Pat. No. 6,859,397, titled “Source Side Self Boosting Technique For Non-Volatile Memory,” and in U.S. Patent Application Publication 2005/0024939, titled “Detecting Over Programmed Memory,” published Feb. 3, 2005; both of which are incorporated herein by reference in their entirety.

In multi-level storage devices, various programming techniques can be used to enhance performance in terms of obtaining narrower programmed threshold voltage (Vt) distributions and higher programming speeds. For example, a coarse/fine verify technique can be used in which an intermediate bit line voltage is applied to storage elements that have reached a specified verify level which is less than the final verify level. This slows down programming so that the Vt can be more precisely controlled. With coarse/fine verify and other approaches, often at least two of the multi-level states of the storage elements are programmed at once and, in some cases, all three programmed states (in the case of a 4-level multi-level memory) are programmed simultaneously, in what is often referred to as the full-sequence method. Full-sequence programming, especially in combination with an all-bitline (ABL) architecture, in which all storage elements on a word line are programmed at the same time rather than in an odd-even pattern, for instance, results in high programming speeds. However, for future memory devices, even higher programming speeds and narrower Vt distributions are needed. An improved programming technique is needed which addresses the above and other issues.

### SUMMARY OF THE INVENTION

The present invention addresses the above and other issues by providing a system and method for operating non-volatile storage in a manner which provides higher programming speeds and narrower Vt distributions.

In one embodiment, programming non-volatile storage includes applying a series of voltage waveforms to non-volatile storage elements, where each voltage waveform includes a first portion followed by a second portion. The non-volatile storage elements include at least a first set of non-volatile storage elements which are to be programmed to a first state and a second set of non-volatile storage elements which are to be programmed to a second state. Non-volatile storage elements in the first set are inhibited from being programmed when the first portion of each voltage waveform is applied to the non-volatile storage elements, and non-volatile storage elements in the first set are allowed to be programmed when the second portion of each voltage waveform is applied to the non-volatile storage elements.

Inhibiting programming may include applying a voltage to bit lines associated with the non-volatile storage elements in the first set which inhibits programming therein, while allowing programming may include applying a voltage to bit lines associated with the non-volatile storage elements in the first set which allows programming therein. Each voltage waveform can have an amplitude which ramps down with time, or steps down with time, for instance.

A corresponding non-volatile storage system includes non-volatile storage elements, and one or more circuits for programming the non-volatile storage elements. The one or more circuits perform the programming by (a) applying a series of voltage waveforms to the non-volatile storage elements, each voltage waveform comprising a first portion followed by a second portion, the non-volatile storage elements include at least a first set of non-volatile storage elements which are to be programmed to a first state and a second set of non-volatile storage elements which are to be programmed to a second state, (b) inhibiting non-volatile storage elements in the first set from being programmed when the first portion of each voltage waveform is applied to the non-volatile storage elements, and (c) allowing non-volatile storage elements in the first set to be programmed when the second portion of each voltage waveform is applied to the non-volatile storage elements.

In another embodiment, programming non-volatile storage includes applying a series of voltage waveforms to non-volatile storage elements, where each voltage waveform includes successive portions with different amplitudes, and the non-volatile storage elements include different sets of non-volatile storage elements which are to be programmed to respective different states. Non-volatile storage elements in one or more of the different sets are inhibited from being programmed, and non-volatile storage elements in one or more others of the different sets are allowed to be programmed, according to which successive portion of the voltage waveform is being applied to the non-volatile storage elements.

In another embodiment, non-volatile storage elements which are to be programmed to two or more states are allowed to be programmed or are inhibited from being programmed in a waveform portion.

### BRIEF DESCRIPTION OF THE DRAWINGS

FIG. 1a is a top view of a NAND string.

FIG. 1b is an equivalent circuit diagram of the NAND string of FIG. 1a.

FIG. 1c is a cross-sectional view of the NAND string of FIG. 1a.

FIG. 2 is a block diagram of a portion of an array of NAND flash memory storage elements.

FIG. 3 is a block diagram of a non-volatile memory system.

FIG. 4 is a block diagram of a non-volatile memory system.

FIG. 5 is a block diagram depicting one embodiment of the sense block.

FIG. 6 is a block diagram of a memory array.

FIG. 7 depicts an example set of threshold voltage distributions.

FIG. 8 depicts an example set of threshold voltage distributions.

FIGS. 9a-c show various threshold voltage distributions and describe a process for programming non-volatile memory.

FIGS. 9d-f show various threshold voltage distributions and describe another process for programming non-volatile memory.

FIGS. 10a and 10b illustrate an example of a traditional programming process for two different non-volatile storage elements.

FIG. 11a illustrates a threshold voltage versus time relationship for a traditional programming process as well as a coarse/fine verify process in which the storage element does not reach a Vt state in between Vver1 and Vver2 at any of the verify points.

FIG. 11b illustrates a threshold voltage versus time relationship for a coarse/fine programming process.

FIG. 11c illustrates a threshold voltage versus time relationship for a modified coarse/fine programming process.

FIGS. 12a, 12b and 12c illustrate bit line voltage versus time relationships for the programming processes of FIGS. 11a, 11b and 11c, respectively.

FIG. 13 illustrates a series of fixed amplitude programming pulses for programming a multi-level non-volatile storage element.

FIG. 14 illustrates threshold voltage distributions for E, A, B and C states using the programming of FIG. 13.

FIG. 15 depicts a timing diagram for a fixed amplitude voltage waveform for programming non-volatile storage.

FIG. 16 depicts a timing diagram for a multi-level voltage waveform for programming non-volatile storage to a C state.

FIG. 17 depicts a timing diagram for a multi-level voltage waveform for programming non-volatile storage to a B state.

FIG. 18 depicts a timing diagram for a multi-level voltage waveform for programming non-volatile storage to an A state.

FIG. 19 depicts a timing diagram for a multi-level voltage waveform for programming non-volatile storage.

FIG. 20a depicts a series of staircase amplitude voltage waveforms used for programming non-volatile storage elements.

FIG. 20b depicts a series of ramped amplitude voltage waveforms used for programming non-volatile storage elements.

FIG. 21 is a flow chart describing one embodiment of a process for programming non-volatile memory using multi-level programming waveforms.

### DETAILED DESCRIPTION

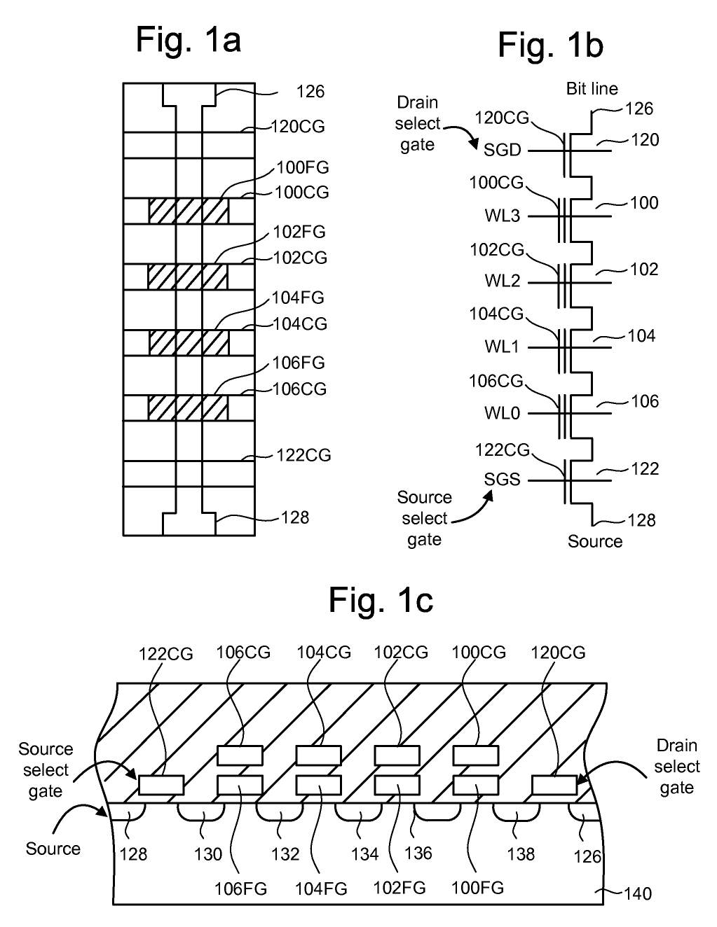

One example of a non-volatile memory system suitable for implementing the present invention uses the NAND flash memory structure, in which multiple transistors are arranged in series between two select gates in a NAND string. FIG. 1a is a top view showing one NAND string. FIG. 1b is an equivalent circuit thereof. The NAND string depicted in FIGS. 1a and 1b includes four transistors, 100, 102, 104 and 106, in series and sandwiched between a first select gate 120 and a second select gate 122. Select gates 120 and 122 connect the NAND string to bit line contact 126 and source line contact 128, respectively. Select gates 120 and 122 are controlled by applying the appropriate voltages to control gates 120CG and 122CG, respectively. Each of the transistors 100, 102, 104 and 106 has a control gate and a floating gate. Transistor 100 has control gate 100CG and floating gate 100FG. Transistor 102 includes control gate 102CG and floating gate 102FG. Transistor 104 includes control gate 104CG and floating gate 104FG. Transistor 106 includes a control gate 106CG and floating gate 106FG. Control gates 100CG, 102CG, 104CG and 106CG are connected to word lines WL3, WL2, WL1 and WL0, respectively. In one possible design, transistors 100, 102, 104 and 106 are each storage elements. In other designs, the memory elements may include multiple transistors or may be different than those depicted in FIGS. 1a and 1b. Select gate 120 is connected to drain select line SGD, while select gate 122 is connected to source select line SGS.

FIG. 1c provides a cross-sectional view of the NAND string described above. The transistors of the NAND string are formed in p-well region 140. Each transistor includes a stacked gate structure that includes a control gate (100CG, 102CG, 104CG and 106CG) and a floating gate (100FG, 102FG, 104FG and 106FG). The floating gates are formed on the surface of the p-well on top of an oxide or other dielectric film. The control gate is above the floating gate, with an inter-polysilicon dielectric layer separating the control gate and floating gate. The control gates of the memory elements (100, 102, 104 and 106) form the word lines. N+ doped layers 130, 132, 134, 136 and 138 are shared between neighboring elements, whereby the elements are connected to one another in series to form the NAND string. These N+ doped layers form the source and drain of each of the elements. For example, N+ doped layer 130 serves as the drain of transistor 122 and the source for transistor 106, N+ doped layer 132 serves as the drain for transistor 106 and the source for transistor 104, N+ doped layer 134 serves as the drain for transistor 104 and the source for transistor 102, N+ doped layer 136 serves as the drain for transistor 102 and the source for transistor 100, and N+ doped layer 138 serves as the drain for transistor 100 and the source for transistor 120. N+ doped layer 126 connects to the bit line for the NAND string, while N+ doped layer 128 connects to a common source line for multiple NAND strings.

Note that although FIGS. 1a-c show four memory elements in the NAND string, the use of four transistors is provided only as an example. A NAND string used with the technology described herein can have less than four memory elements or more than four memory elements. For example, some NAND strings will include eight, sixteen, thirty-two, sixty-four or more memory elements. The discussion herein is not limited to any particular number of memory elements in a NAND string.

Generally, the invention can be used with devices that are programmed and erased by Fowler-Nordheim tunneling. The invention is also applicable to devices that use the nitride layer of a triple layer dielectric such as a dielectric formed of silicon oxide, silicon nitride and silicon oxide (ONO) to store charges instead of a floating gate. A triple layer dielectric formed of ONO is sandwiched between a conductive control gate and a surface of a semi-conductive substrate above the memory element channel. In some cases more than three dielectric layers may be used. Other layers, such as aluminum oxide, maybe used as well. An example of the latter is the Si-Oxide-SiN—Al₂O₃—TaN (TANOS) structure in which a triple layer of silicon oxide, silicon nitride and aluminum oxide is used. The invention can also be applied to devices that use, for example, small islands of conducting materials such as nano crystals as charge storage regions instead of floating gates. Such memory devices can be programmed and erased in a similar way as floating gate based NAND flash devices.

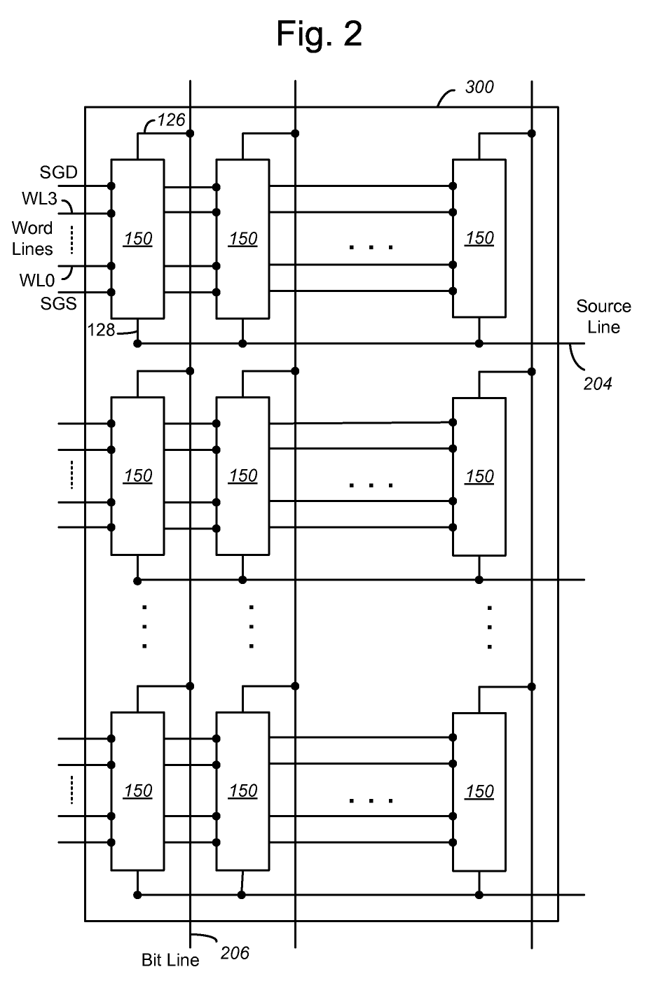

FIG. 2 illustrates an example of an array of NAND storage elements, such as those shown in FIGS. 1a-c. Along each column, a bit line 206 is coupled to the drain terminal 126 of the drain select gate for the NAND string 150. Along each row of NAND strings, a source line 204 may connect all the source terminals 128 of the source select gates of the NAND strings. An example of a NAND architecture array and its operation as part of a memory system is found in U.S. Pat. Nos. 5,570,315; 5,774,397; and 6,046,935.

The array of storage elements is divided into a large number of blocks of storage elements. As is common for flash EEPROM systems, the block is the unit of erase. That is, each block contains the minimum number of storage elements that are erased together. Each block is typically divided into a number of pages. A page is a unit of programming. In one embodiment, the individual pages may be divided into sectors and the sectors may contain the fewest number of storage elements that are written at one time as a basic programming operation. One or more pages of data are typically stored in one row of storage elements. A page can store one or more sectors. A sector includes user data and overhead data. Overhead data typically includes an Error Correction Code (ECC) that has been calculated from the user data of the sector. A portion of the controller (described below) calculates the ECC when data is being programmed into the array, and also checks it when data is being read from the array. Alternatively, the ECCs and/or other overhead data are stored in different pages, or even different blocks, than the user data to which they pertain. A sector of user data is typically 512 bytes, corresponding to the size of a sector in magnetic disk drives. Overhead data is typically an additional 16-20 bytes. A large number of pages form a block, anywhere from 8 pages, for example, up to 32, 64, 128 or more pages.

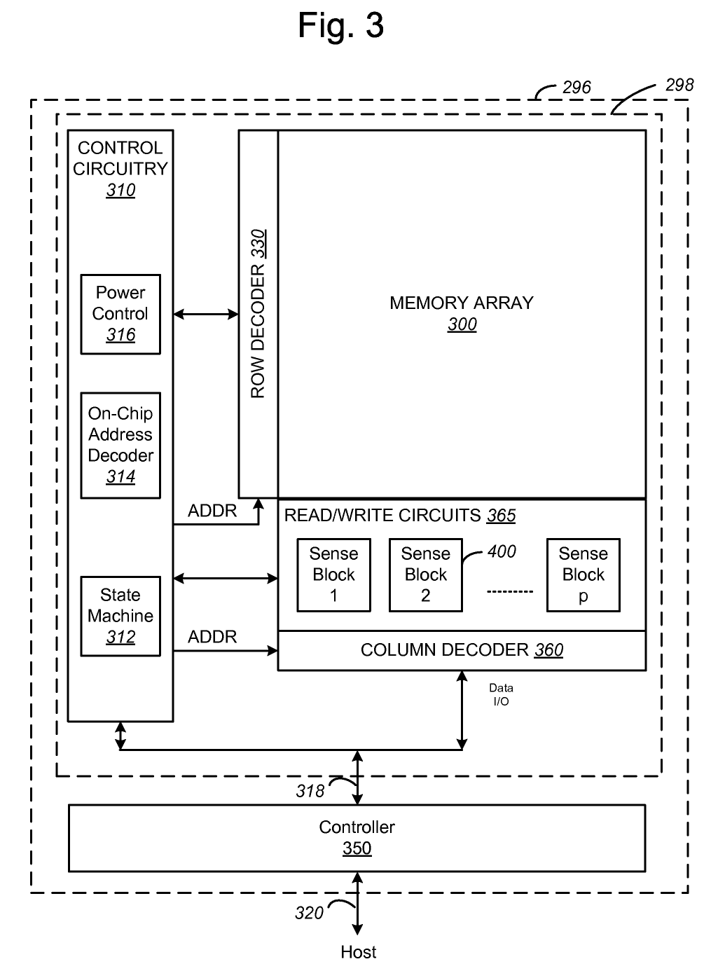

FIG. 3 illustrates a memory device 296 having read/write circuits for reading and programming a page of storage elements in parallel, according to one embodiment of the present invention. Memory device 296 may include one or more memory die 298. Memory die 298 includes a two-dimensional array of storage elements 300, control circuitry 310, and read/write circuits 365. In some embodiments, the array of storage elements can be three dimensional. The memory array 300 is addressable by word lines via a row decoder 330 and by bit lines via a column decoder 360. The read/write circuits 365 include multiple sense blocks 400 and allow a page of storage elements to be read or programmed in parallel. Typically a controller 350 is included in the same memory device 296 (e.g., a removable storage card) as the one or more memory die 298. Commands and Data are transferred between the host and controller 350 via lines 320 and between the controller and the one or more memory die 298 via lines 318.

The control circuitry 310 cooperates with the read/write circuits 365 to perform memory operations on the memory array 300. The control circuitry 310 includes a state machine 312, an on-chip address decoder 314 and a power control module 316. The state machine 312 provides chip-level control of memory operations. The on-chip address decoder 314 provides an address interface between that used by the host or a memory controller to the hardware address used by the decoders 330 and 360. The power control module 316 controls the power and voltages supplied to the word lines and bit lines during memory operations.

In some implementations, some of the components of FIG. 3 can be combined. In various designs, one or more of the components of FIG. 3 (alone or in combination), other than storage element array 300, can be thought of as a managing circuit. For example, a managing circuits may include any one of or a combination of control circuitry 310, state machine 312, decoders 314/360, power control 316, sense blocks 400, read/write circuits 365, controller 350, etc.

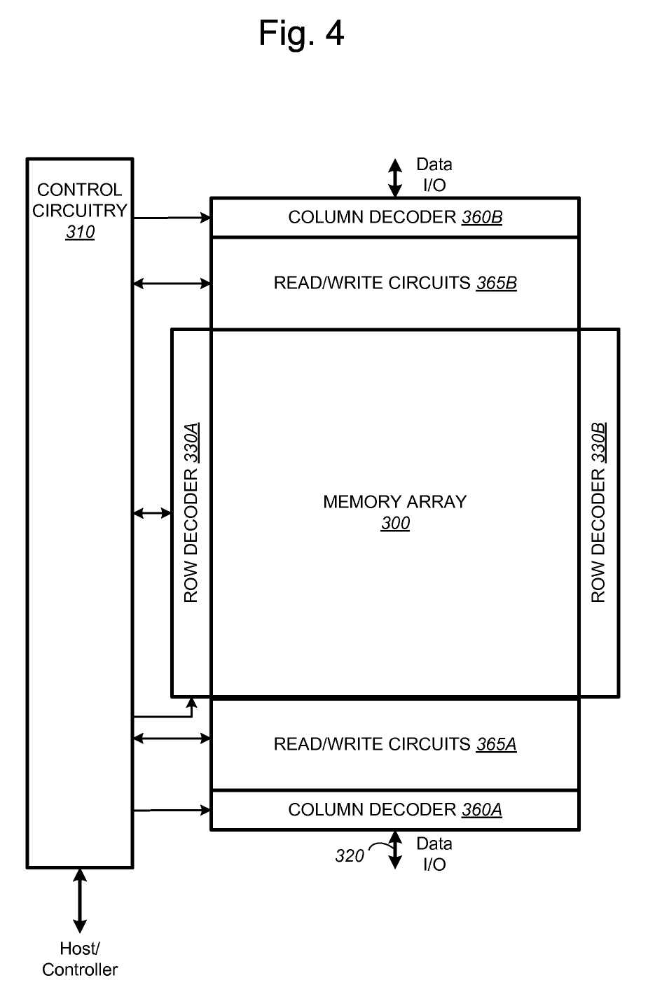

FIG. 4 illustrates another arrangement of the memory device 296 shown in FIG. 3. Access to the memory array 300 by the various peripheral circuits is implemented in a symmetric fashion, on opposite sides of the array, so that the densities of access lines and circuitry on each side are reduced by half. Thus, the row decoder is split into row decoders 330A and 330B and the column decoder into column decoders 360A and 360B. Similarly, the read/write circuits are split into read/write circuits 365A connecting to bit lines from the bottom and read/write circuits 365B connecting to bit lines from the top of the array 300. In this way, the density of the read/write modules is essentially reduced by one half. The device of FIG. 4 can also include a controller, as described above for the device of FIG. 3.

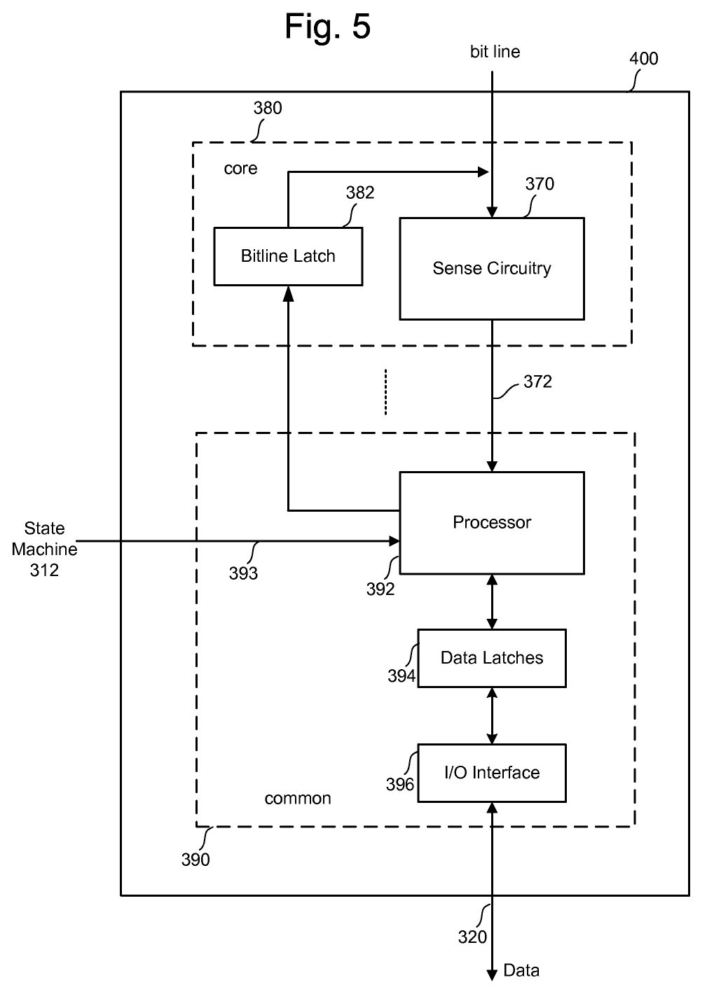

FIG. 5 is a block diagram of an individual sense block 400 partitioned into a core portion, referred to as a sense module 380, and a common portion 390. In one embodiment, there will be a separate sense module 380 for each bit line and one common portion 390 for a set of multiple sense modules 380. In one example, a sense block will include one common portion 390 and eight sense modules 380. Each of the sense modules in a group will communicate with the associated common portion via a data bus 372. For further details, refer to U.S. patent application Ser. No. 11/026,536 “Non-Volatile Memory & Method with Shared Processing for an Aggregate of Sense Amplifiers” filed on Dec. 29, 2004, which is incorporated herein by reference in its entirety.

Sense module 380 comprises sense circuitry 370 that determines whether a conduction current in a connected bit line is above or below a predetermined threshold level. Sense module 380 also includes a bit line latch 382 that is used to set a voltage condition on the connected bit line. For example, a predetermined state latched in bit line latch 382 will result in the connected bit line being pulled to a state designating program inhibit (e.g., Vdd).

Common portion 390 comprises a processor 392, a set of data latches 394 and an I/O Interface 396 coupled between the set of data latches 394 and data bus 320. Processor 392 performs computations. For example, one of its functions is to determine the data stored in the sensed storage element and store the determined data in the set of data latches. The set of data latches 394 is used to store data bits determined by processor 392 during a read operation. It is also used to store data bits imported from the data bus 320 during a program operation. The imported data bits represent write data meant to be programmed into the memory. I/O interface 396 provides an interface between data latches 394 and the data bus 320.

During read or sensing, the operation of the system is under the control of state machine 312 that controls the supply of different control gate voltages to the addressed storage elements. As it steps through the various predefined control gate voltages corresponding to the various memory states supported by the memory, the sense module 380 may trip at one of these voltages and an output will be provided from sense module 380 to processor 392 via bus 372. At that point, processor 392 determines the resultant memory state by consideration of the tripping event(s) of the sense module and the information about the applied control gate voltage from the state machine via input lines 393. It then computes a binary encoding for the memory state and stores the resultant data bits into data latches 394. In another embodiment of the core portion, bit line latch 382 serves double duty, both as a latch for latching the output of the sense module 380 and also as a bit line latch as described above.

It is anticipated that some implementations will include multiple processors 392. In one embodiment, each processor 392 will include an output line (not depicted in FIG. 5) such that each of the output lines is wired-OR'd together. In some embodiments, the output lines are inverted prior to being connected to the wired-OR line. This configuration enables a quick determination during the program verification process of when the programming process has completed because the state machine receiving the wired-OR can determine when all storage elements being programmed have reached the desired level. For example, when each storage element has reached its desired level, a logic zero for that storage element will be sent to the wired-OR line (or a data one is inverted). When all output lines output a data 0 (or a data one inverted), then the state machine knows to terminate the programming process. Because each processor communicates with eight sense modules, the state machine needs to read the wired-OR line eight times, or logic is added to processor 392 to accumulate the results of the associated bit lines such that the state machine need only read the wired-OR line one time.

During program or verify, the data to be programmed is stored in the set of data latches 394 from the data bus 320. The program operation, under the control of the state machine, comprises a series of programming voltage pulses applied to the control gates of the addressed storage elements. Each programming pulse is followed by a verify operation to determine if the storage element has been programmed to the desired state. Processor 392 monitors the verified memory state relative to the desired memory state. When the two are in agreement, the processor 392 sets the bit line latch 382 so as to cause the bit line to be pulled to a state designating program inhibit. This inhibits the storage element coupled to the bit line from further programming even if programming pulses appear on its control gate. In other embodiments the processor initially loads the bit line latch 382 and the sense circuitry sets it to an inhibit value during the verify process.

Data latch stack 394 contains a stack of data latches corresponding to the sense module. In one embodiment, there are three data latches per sense module 380. In some implementations (but not required), the data latches are implemented as a shift register so that the parallel data stored therein is converted to serial data for data bus 320, and vice versa. In the preferred embodiment, all the data latches corresponding to the read/write block of m storage elements can be linked together to form a block shift register so that a block of data can be input or output by serial transfer. In particular, the bank of r read/write modules is adapted so that each of its set of data latches will shift data in to or out of the data bus in sequence as if they are part of a shift register for the entire read/write block.

Additional information about the structure and/or operations of various embodiments of non-volatile storage devices can be found in (1) United States Patent Application Pub. No. 2004/0057287, “Non-Volatile Memory And Method With Reduced Source Line Bias Errors,” published on Mar. 25, 2004; (2) United States Patent Application Pub No. 2004/0109357, “Non-Volatile Memory And Method with Improved Sensing,” published on Jun. 10, 2004; (3) U.S. patent application Ser. No. 11/015,199 titled “Improved Memory Sensing Circuit And Method For Low Voltage Operation,” Inventor Raul-Adrian Cernea, filed on Dec. 16, 2004; (4) U.S. patent application Ser. No. 11/099,133, titled “Compensating for Coupling During Read Operations of Non-Volatile Memory,” Inventor Jian Chen, filed on Apr. 5, 2005; and (5) U.S. patent application Ser. No. 11/321,953, titled “Reference Sense Amplifier For Non-Volatile Memory, Inventors Siu Lung Chan and Raul-Adrian Cernea, filed on Dec. 28, 2005. All five of the immediately above-listed patent documents are incorporated herein by reference in their entirety.

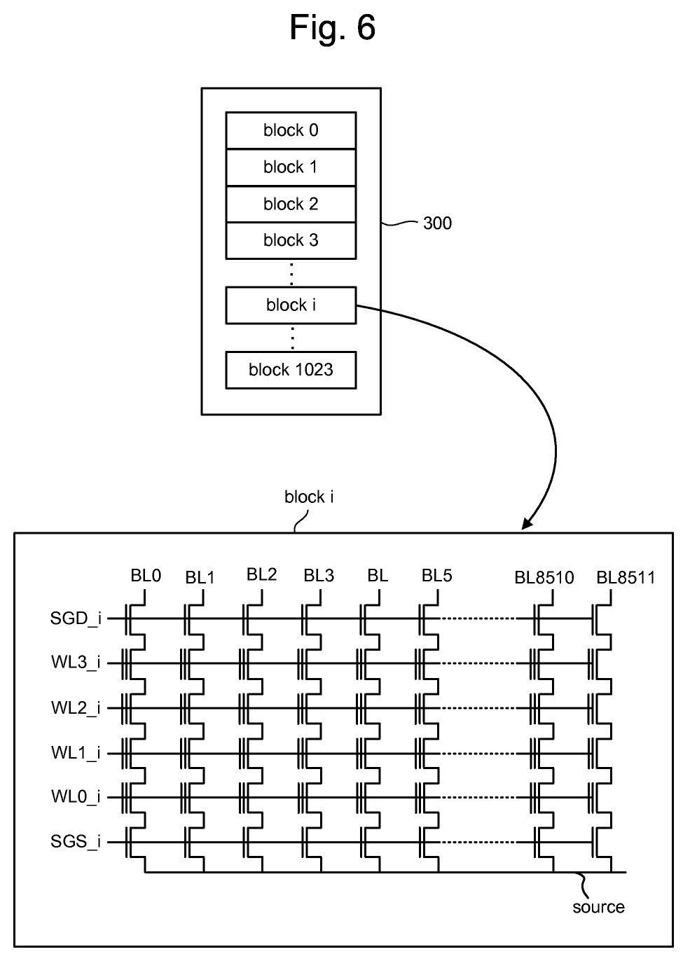

With reference to FIG. 6, an exemplary structure of storage element array 302 is described. As one example, a NAND flash EEPROM is described that is partitioned into 1,024 blocks. The data stored in each block can be simultaneously erased. In one embodiment, the block is the minimum unit of storage elements that are simultaneously erased. In each block, in this example, there are 8,512 columns corresponding to bit lines BL0, BL1, . . . BL8511. In one embodiment, all the bit lines of a block can be simultaneously selected during read and program operations. Storage elements along a common word line and connected to any bit line can be programmed at the same time.

In another embodiment, the bit lines are divided into even bit lines and odd bit lines. In an odd/even bit line architecture, storage elements along a common word line and connected to the odd bit lines are programmed at one time, while storage elements along a common word line and connected to even bit lines are programmed at another time.

FIG. 6 shows four storage elements connected in series to form a NAND string. Although four storage elements are shown to be included in each NAND string, more or less than four can be used (e.g., 16, 32, or another number). One terminal of the NAND string is connected to a corresponding bit line via a drain select gate (connected to select gate drain line SGD), and another terminal is connected to c-source via a source select gate (connected to select gate source line SGS).

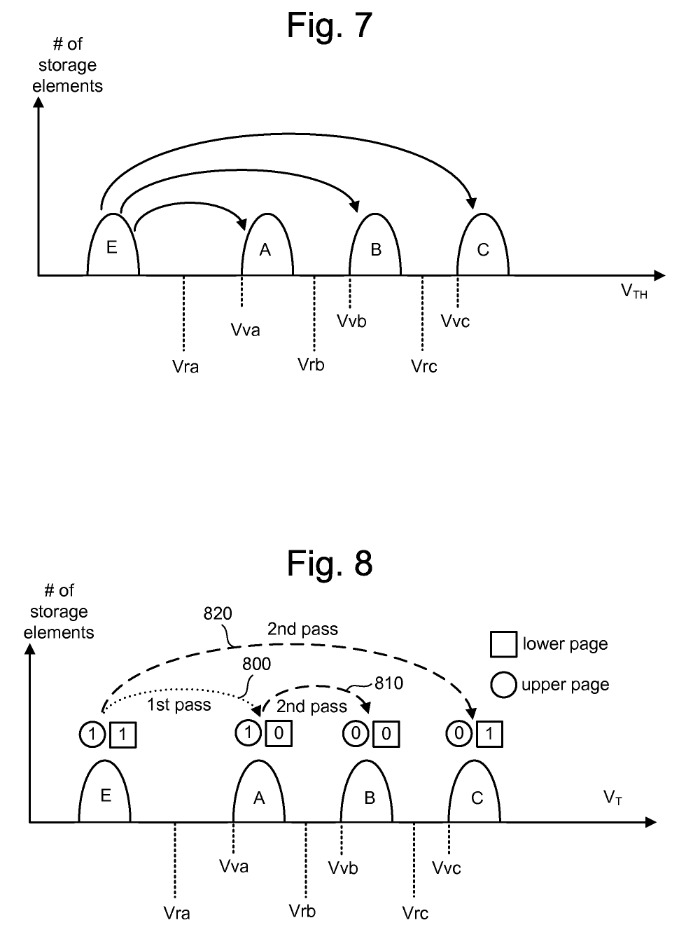

FIG. 7 illustrates example threshold voltage distributions for the storage element array when each storage element stores two bits of data. FIG. 7 shows a first threshold voltage distribution E for erased storage elements. Three threshold voltage distributions, A, B and C for programmed storage elements, are also depicted. In one embodiment, the threshold voltages in the E distribution are negative and the threshold voltages in the A, B and C distributions are positive.

Each distinct threshold voltage range of FIG. 7 corresponds to predetermined values for the set of data bits. The specific relationship between the data programmed into the storage element and the threshold voltage levels of the storage element depends upon the data encoding scheme adopted for the storage elements. For example, U.S. Pat. No. 6,222,762 and U.S. Patent Application Publication No. 2004/0255090, “Tracking Cells For A Memory System,” filed on Jun. 13, 2003, both of which are incorporated herein by reference in their entirety, describe various data encoding schemes for multi-state flash storage elements. In one embodiment, data values are assigned to the threshold voltage ranges using a Gray code assignment so that if the threshold voltage of a floating gate erroneously shifts to its neighboring physical state, only one bit will be affected. One example assigns “11” to threshold voltage range E (state E), “10” to threshold voltage range A (state A), “00” to threshold voltage range B (state B) and “01” to threshold voltage range C (state C). However, in other embodiments, Gray code is not used. Although FIG. 7 shows four states, the present invention can also be used with other multi-state structures including those that include more or less than four states.

FIG. 7 also shows three read reference voltages, Vra, Vrb and Vrc, for reading data from storage elements. By testing whether the threshold voltage of a given storage element is above or below Vra, Vrb and Vrc, the system can determine what state the storage element is in. FIG. 7 also shows three verify reference voltages, Vva, Vvb and Vvc. When programming storage elements to state A, the system will test whether those storage elements have a threshold voltage greater than or equal to Vva. When programming storage elements to state B, the system will test whether the storage elements have threshold voltages greater than or equal to Vvb. When programming storage elements to state C, the system will determine whether storage elements have their threshold voltage greater than or equal to Vvc.

In one embodiment, known as full sequence programming, storage elements can be programmed from the erase state E directly to any of the programmed states A, B or C. For example, a population of storage elements to be programmed may first be erased so that all storage elements in the population are in erased state E. While some storage elements are being programmed from state E to state A, other storage elements are being programmed from state E to state B and/or from state E to state C.

FIG. 8 illustrates an example of a two-pass technique of programming a multi-state storage element that stores data for two different pages: a lower page and an upper page. Four states are depicted: state E (11), state A (10), state B (00) and state C (01). For state E, both pages store a “1.” For state A, the lower page stores a “0” and the upper page stores a “1.” For state B, both pages store “0.” For state C, the lower page stores “1” and the upper page stores “0.” Note that although specific bit patterns have been assigned to each of the states, different bit patterns may also be assigned.

In a first programming pass, the storage element's threshold voltage level is set according to the bit to be programmed into the lower logical page. If that bit is a logic “1,” the threshold voltage is not changed since it is in the appropriate state as a result of having been earlier erased. However, if the bit to be programmed is a logic “0,” the threshold level of the storage element is increased to be state A, as shown by arrow 800.

In a second programming pass, the storage element's threshold voltage level is set according to the bit being programmed into the upper logical page. If the upper logical page bit is to store a logic “1,” then no programming occurs since the storage element is in one of the states E or A, depending upon the programming of the lower page bit, both of which carry an upper page bit of “1.” If the upper page bit is to be a logic “0,” then the threshold voltage is shifted. If the first pass resulted in the storage element remaining in the erased state E, then in the second phase the storage element is programmed so that the threshold voltage is increased to be within state C, as depicted by arrow 820. If the storage element had been programmed into state A as a result of the first programming pass, then the storage element is further programmed in the second pass so that the threshold voltage is increased to be within state B, as depicted by arrow 810. The result of the second pass is to program the storage element into the state designated to store a logic “0” for the upper page without changing the data for the lower page.

In one embodiment, a system can be set up to perform full sequence writing if enough data is written to fill up a word line. If not enough data is written, then the programming process can program the lower page programming with the data received. When subsequent data is received, the system will then program the upper page. In yet another embodiment, the system can start writing in the mode that programs the lower page and convert to full sequence programming mode if enough data is subsequently received to fill up an entire (or most of a) word line's storage elements. More details of such an embodiment are disclosed in U.S. Patent Application Publication No. 2006/0126390, dated Jun. 15, 2006, titled “Pipelined Programming of Non-Volatile Memories Using Early Data,” incorporated herein by reference in its entirety.

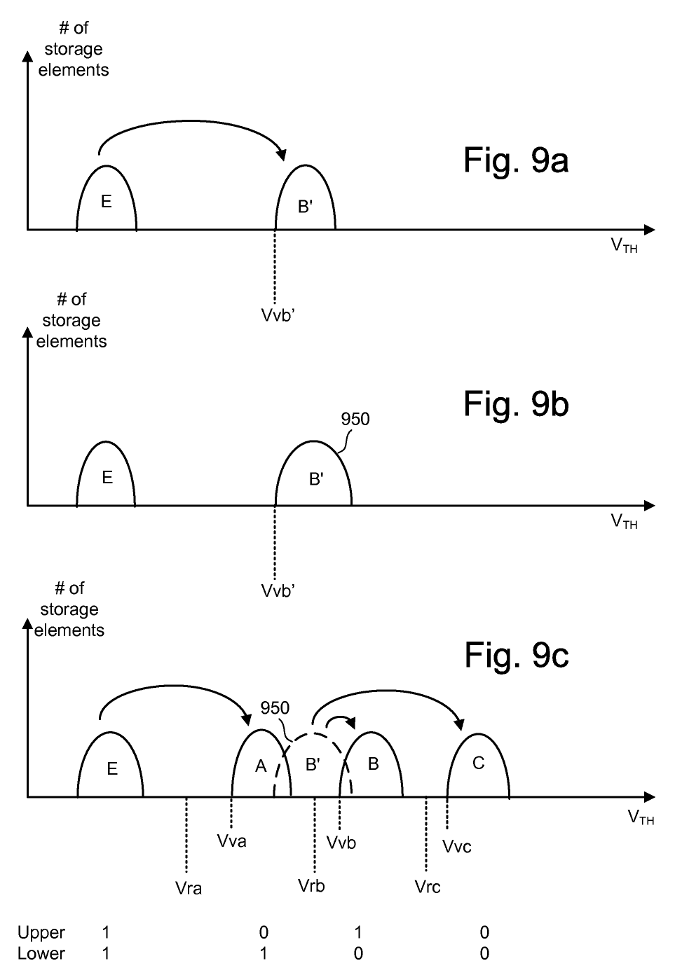

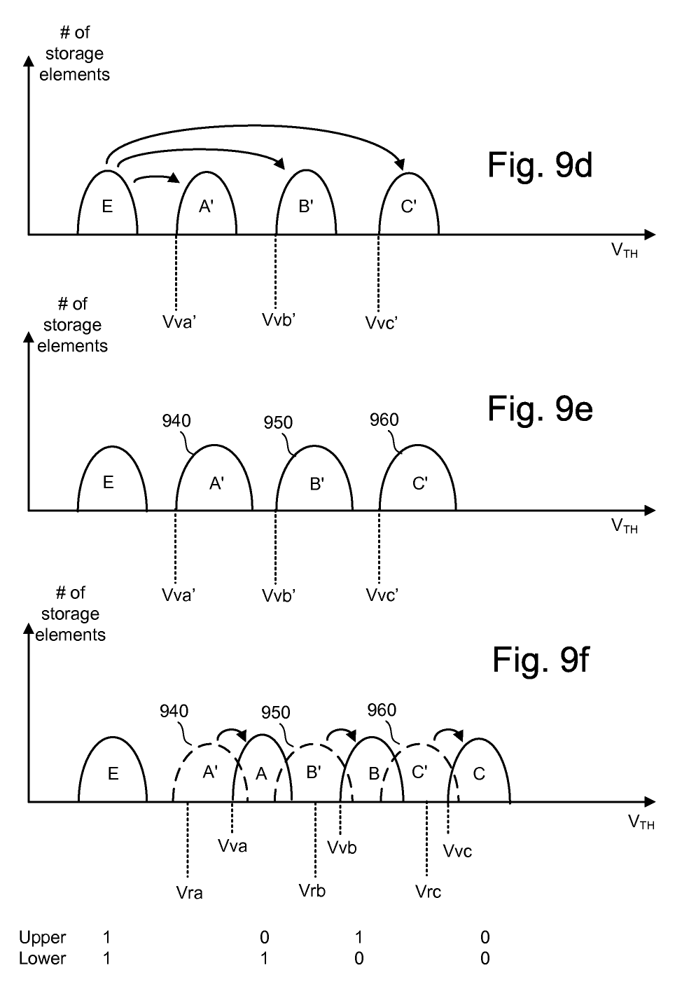

FIGS. 9a-c depict another process for programming non-volatile memory that reduces floating gate-to-floating gate coupling by, for any particular memory element, writing to that particular memory element with respect to a particular page subsequent to writing to adjacent memory elements for previous pages. In one example implementation, each of the non-volatile memory elements store two bits of data, using four data states. For example, assume that state E is the erased state and states A, B and C are the programmed states. State E stores data 11, state A stores data 01, state B stores data 10 and state C stores data 00. This is an example of non-Gray coding because both bits change between adjacent states A and B. Other encodings of data to physical data states can also be used. Each memory element stores bits from two pages of data. For reference purposes these pages of data will be called upper page and lower page; however, they can be given other labels. For state A, the upper page stores bit 0 and the lower page stores bit 1. For state B, the upper page stores bit 1 and the lower page stores bit 0. For state C, both pages store bit data 0. The programming process has two steps. In the first step, the lower page is programmed. If the lower page is to remain data 1, then the memory element state remains at state E. If the data is to be programmed to 0, then the threshold voltage Vt of the memory element is raised such that the memory element is programmed to state B′. FIG. 9a therefore shows the programming of memory elements from state E to state B′, which represents an interim state B; therefore, the verify point is depicted as Vvb′, which is lower than Vvb, depicted in FIG. 9c.

In one design, after a memory element is programmed from state E to state B′, its neighbor memory element on an adjacent word line is programmed with respect to its lower page. After programming the neighbor memory element, the floating gate-to-floating gate coupling effect will raise the apparent threshold voltage of memory element under consideration, which is in state B′. This will have the effect of widening the threshold voltage distribution for state B′ to that depicted as threshold voltage distribution 950 in FIG. 9b. This apparent widening of the threshold voltage distribution will be remedied when programming the upper page.

FIG. 9c depicts the process of programming the upper page. If the memory element is in erased state E and the upper page is to remain at 1, then the memory element will remain in state E. If the memory element is in state E and its upper page data is to be programmed to 0, the threshold voltage of the memory element will be raised so that the memory element is in state A. If the memory element is in state B′ with the intermediate threshold voltage distribution 950 and the upper page data is to remain at 1, the memory element will be programmed to final state B. If the memory element is in state B′ with the intermediate threshold voltage distribution 950 and the upper page data is to become data 0, the threshold voltage of the memory element will be raised so that the memory element is in state C. The process depicted by FIGS. 9a-c reduces the effect of floating gate-to-floating gate coupling because only the upper page programming of neighbor memory elements will have an effect on the apparent threshold voltage of a given memory element. An example of an alternate state coding is to move from distribution 450 to state C when the upper page data is a 1, and to move to state B when the upper page data is a 0. Although FIGS. 9a-c provide an example with respect to four data states and two pages of data, the concepts taught can be applied to other implementations with more or fewer than four states and more or fewer than two pages. More detail about various programming schemes and floating gate-to-floating gate coupling can be found in U.S. patent application Ser. No. 11/099,133, titled “Compensating For Coupling During Read Operations Of Non-Volatile Memory,” filed on Apr. 5, 2005.

FIGS. 9d-f show various threshold voltage distributions and describe another process for programming non-volatile memory. This approach is similar to that of FIGS. 9a-c except that interim states A′ and C′ are used in addition to B′. Thus, if the lower page is to remain data 1 and the upper page is to remain data 1, then the memory element state remains at state E. If the data is to be programmed to 1 for the lower page and 0 for the upper page, then the Vt of the memory element is raised such that the memory element is programmed to state A′. If the data is to be programmed to 0 for the lower page and 1 for the upper page, then the Vt of the memory element is raised such that the memory element is programmed to state B′. If the data is to be programmed to 0 for the lower page and 0 for the upper page, then the Vt of the memory element is raised such that the memory element is programmed to state C′.

FIG. 9d therefore shows the programming of memory elements from state E to state A′, B′ or C′, which represent interim states A, B and C, respectively; therefore, the verify points are depicted as Vva′, Vvb′ and Vvc′, which are lower than Vva, Vvb and Vvc, respectively, depicted in FIG. 9f.

In one design, after a memory element is programmed from state E to state A′, B′ or C′, its neighbor memory element on an adjacent word line is programmed. After programming the neighbor memory element, the floating gate-to-floating gate coupling effect will raise the apparent threshold voltage of memory element under consideration, which is in state A′, B′ or C′. This will have the effect of widening the threshold voltage distribution for state A′, B′ or C′ to that depicted as threshold voltage distribution 940, 950 or 960 in FIG. 9e. This apparent widening of the threshold voltage distribution will be remedied during a next programming pass, as depicted in FIG. 9f. The memory elements in state A′, B′ or C′ with the intermediate threshold voltage distributions 940, 950 and 960, respectively, are programmed to the final state A, B or C, respectively. The process depicted reduces the effect of floating gate-to-floating gate coupling further compared to the programming of FIGS. 9a-c because the shift in Vt of the neighbor memory elements is much smaller during the second programming pass. Although FIGS. 9d-f provide an example with respect to four data states and two pages of data, the concepts taught can be applied to other implementations with more or fewer than four states and more or fewer than two pages.

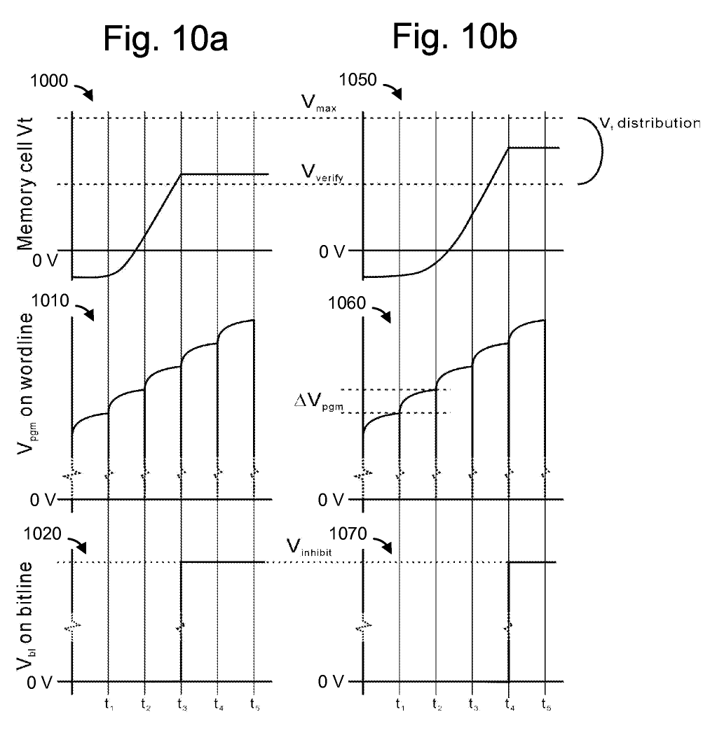

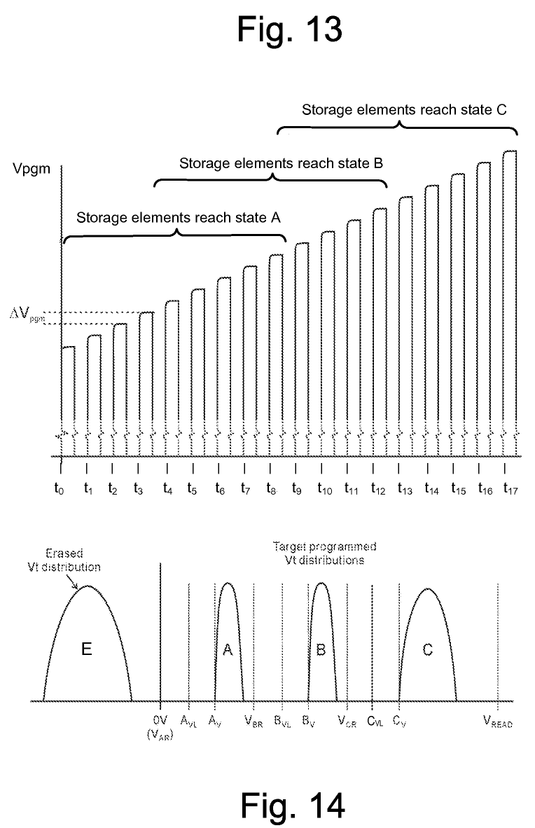

FIGS. 10a and 10b illustrate an example of a traditional programming process for two different non-volatile storage elements. The traditional programming process can be used for programming both binary and multi-level NAND storage devices. The storage element depicted by the graphs of FIG. 10a programs faster than that indicated by the graphs of FIG. 10b due to normal variations in storage element characteristics. Graphs 1000 and 1050 depict the threshold voltages (Vt) of the storage elements, graphs 1010 and 1060 depict the programming voltage Vpgm on a word line, which is the same in both cases, and graphs 1020 and 1070 depict the bitline voltage associated with the programmed storage elements. Note that the graphs 1010 and 1060 provide a simplification of the programming voltage Vpgm. In practice, a programming voltage similar to that of FIG. 13 can be provided where there are spaces between programming pulses. Additionally, verify pulses are provided between the programming pulses.

At certain time intervals during programming, t₁, t₂, t₃, . . . , a verify operation is carried out in which the Vt of the storage element/storage element is measured. If the Vt of the storage element is lower than the value of a verify voltage, Vverify, programming continues for that storage element. That is, the bitline voltage stays low, typically at 0 V. However, when the Vt of the storage element is higher than the verify voltage, programming during the subsequent programming pulses is inhibited by raising the bitline of the corresponding storage element to a high voltage, typically to the power supply voltage Vdd. In combination with the self-boosting method, or any other self-boosting method such as LSB or EASB, for instance, the channel area under the inhibited storage element will be boosted and therefore inhibit further programming of that storage element.

For example, graph 1000 indicates that the associated storage element reaches the verify level at t₃, at which point the bitline voltage steps up to the inhibit level, Vinhibit, as shown by graph 1020, and the storage element is locked out from further programming. Graph 1050 indicates that the associated storage element reaches the verify level at t₄, at which point the bitline voltage steps up to the inhibit level, Vinhibit, as shown by graph 1070, and the storage element is locked out from further programming. Graphs 1010 and 1060 show that, for each programming pulse, the programming voltage is increased by a fixed amount, ΔVpgm, as a result of which the Vt of the storage element during one programming pulse also increases by about the same amount, once the storage element has reached a linear programming regime. Generally, the Vt which is reached by each storage element programmed to the same state is within a Vt distribution as indicated, between Vverify and a maximum level, Vmax.

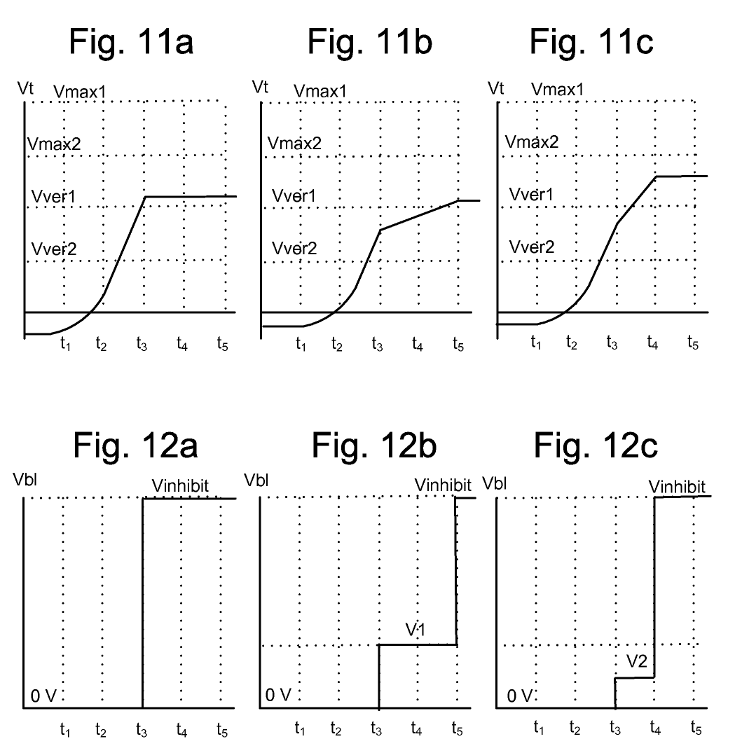

FIG. 1a illustrates a threshold voltage versus time relationship for a traditional programming process as well as a coarse/fine verify process in which the storage element does not reach a Vt state in between Vver1 and Vver2 at any of the verify points, while FIG. 11b illustrates a threshold voltage versus time relationship for a coarse/fine programming process, and FIG. 11c illustrates a threshold voltage versus time relationship for a modified coarse/fine programming process. FIGS. 12a, 12b and 12c illustrate bit line voltage (Vb1) versus time relationships for the programming processes of FIGS. 11a, 11b and 11c, respectively. The coarse/fine technique is used mainly in programming multi-level NAND storage elements, but can be used in programming binary devices as well. FIGS. 11a-c depict the threshold voltages (Vt) of the storage elements, and FIGS. 12a-c depict the corresponding bitline voltages associated with the programmed storage elements. At certain time intervals or verify points during programming, t₁, t₂, t₃, . . . , a verify operation is carried out in which the threshold voltage (Vt) of the storage element is measured.

As shown by FIGS. 11a and 12a, if the Vt of the storage element is lower than the value of a lower verify level, Vver2, programming continues for that storage element without inhibiting programming of the storage element. That is, the bitline voltage (Vb1) stays low, typically at 0 V. The storage element essentially bypasses the range between Vver1 and Vver2 between verify points t₂ and t₃. As a result, in both the traditional and coarse/fine programming of the example, the storage element is fully inhibited at t₃ without undergoing any partial inhibiting. At t₃, the storage element reaches a Vt state above Vver1, at which time Vb1 steps up from 0 V to Vinhibit, which is typically the power supply voltage, Vdd, to fully inhibit programming. Thus, programming continues until Vt reaches the higher verify level, Vver1, after which programming during the subsequent programming pulses is inhibited by raising the bitline of the corresponding storage element to the inhibit voltage, Vinhibit.

FIG. 11b represents an example of the coarse/fine programming process, and indicates how the storage element is partially inhibited from programming at t₃ when it reaches a Vt state in between Vver1 and Vver2, at which time the bit line voltage steps up to V1 (FIG. 12b). V1 is set at an intermediate level, typically about 0.7 V, which partially inhibits programming of the storage element. The channel voltage during programming will also be about the same as V1. At t₄, Vt is still between Vver2 and Vver1, so Vb1 remains at V1. At t₅, the storage element reaches a Vt state above Vver1, at which time the bit line voltage steps up from V1 to Vinhibit to fully inhibit programming. With the coarse/fine programming processes, the programmed Vt distribution is narrower than with the traditional programming process because the storage element's Vt shift is reduced once the Vt has come close to the target Vt value of the desired programmed state.

FIG. 11c represents an example of a modified coarse/fine programming process in which a reduced inhibit voltage V2 is used, where V2<V1. In this example, the storage element is partially inhibited from programming at t₃ when it reaches a Vt state in between Vver1 and Vver2, at which time the bit line voltage steps up to V2 (FIG. 12c). The channel voltage during programming will also be about the same as V2. Since V2<V1, the rate at which the storage element is programmed when Vb1=V2 is less than if Vb1=V1. That is, programming of the storage element is slowed down less than with the traditional coarse/fine programming process. At the next verify time t₄, after one additional programming pulse has been applied, the storage element reaches a Vt state above Vver1, at which time Vb1 steps up from V1 to Vinhibit to fully inhibit programming.

With the modified coarse/fine programming, in order to obtain the best performance, V1 should be chosen in such a way that the Vt shift of the storage element during the next programming pulse, equals ΔVpgm/2. For example, V1=0.3 V. If Vver1 and Vver2 are chosen in an appropriate way, the Vt of the storage element should then be higher than Vver1 (the target value) after only one additional programming pulse. Only one additional programming pulse is provided regardless of whether the storage element's Vt after that one additional pulse is higher or lower than the final target level, Vver1. An advantage of the modified coarse/fine programming process is that fewer programming pulses are needed than with the traditional coarse/fine programming process, resulting a shorter programming time and reduced program disturb, especially when used for the highest programmed Vt state.

FIG. 13 illustrates a series of fixed amplitude programming pulses for programming a multi-level non-volatile storage element. The programming pulses are applied to the word line selected for programming. In between the program pulses are a set of verify pulses (not depicted). In some embodiments, there can be a verify pulse for each state that data is being programmed into. In other embodiments, there can be more or fewer verify pulses. In one embodiment, data is programmed to storage elements along a common word line. Thus, prior to applying the program pulses, one of the word lines is selected for programming. This word line will be referred to as the selected word line. The remaining word lines of a block are referred to as the unselected word lines. The selected word line may have one or two neighboring word lines. If the selected word line has two neighboring word lines, then the neighboring word line on the drain side is referred to as the drain side neighboring word line and the neighboring word line on the source side is referred to as the source side neighboring word line.

In particular, programming of multi-level storage elements is achieved here by applying successive fixed-amplitude programming pulses, where the fixed-amplitude increases for successive pulses. With full sequence programming, distributions A, B and C are programmed at the same time. Typically, coarse/fine verify is used for the A and B states while the traditional programming process is used for the C state. In the example provided, it takes about nine pulses to program each Vt state, with the A state being programmed first, the B state being programmed next, and the C state being programmed last. Although all three states are programmed at the same time, a higher programming voltage is required for the B and C state storage elements, and thus more programming pulses are needed with an increasing programming voltage after the A state has finished programming.

FIG. 14 illustrates threshold voltage distributions for E, A, B and C states using the programming of FIG. 13. The Vt distributions are achieved using coarse/fine verify for the A and B states, while traditional write is used for the C state. Thus, the Vt distribution for the C state is wider than that for the A and B states. The E state represents the erased state. V_{AR}, V_{BR} and V_{CR} represent the read voltages for the A, B and C states, respectively. A_{VL}, B_{VL} and C_{VL} represent lower verify levels for coarse/fine programming for the A, B and C states, respectively, although in many cases, coarse/fine programming for the C state is not used. A_{V}, B_{V} and C_{V} represent the verify voltages for the A, B and C states, respectively. These are the upper verify levels for coarse/fine programming, when used.

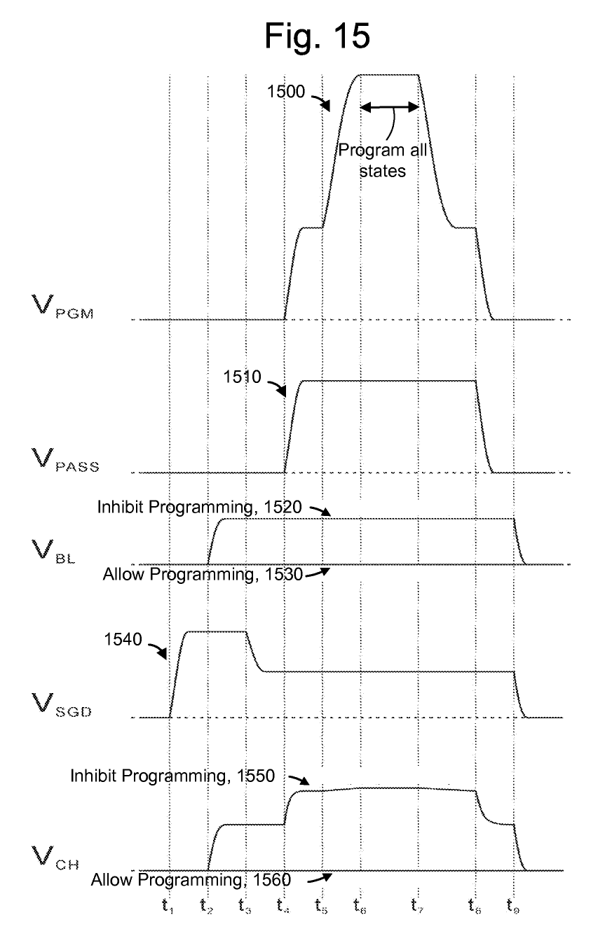

FIG. 15 depicts a timing diagram for a fixed amplitude voltage waveform for programming non-volatile storage. Curve 1500 depicts the programming voltage waveform, Vpgm, which is applied to a word line associated with storage elements that are currently being programmed, and curve 1510 depicts a pass voltage, Vpass, which is applied to other word lines. Curve 1520 depicts the bitline voltage, V_{BL}, for a storage element which is inhibited from being programmed while Vpgm is applied, and curve 1530 depicts the bitline voltage for a storage element which is allowed to be programmed when Vpgm is applied. Curve 1540 depicts the drain side select gate voltage, V_{SGD}, of a NAND string. Curve 1550 depicts the channel voltage, V_{CH}, for the storage element when the V_{BL} 1520 is applied, and curve 1560 depicts V_{CH} for the storage element when the V_{BL} 1530 is applied.

At t₁, the drain side select gate is opened by applying a relatively high voltage, e.g., 3-4.5 V. Note that the source side select gate remains biased at 0 V. Subsequently, at t₂, the bitline voltage V_{BL} is applied for either programming a storage element, in which case V_{BL} is 0 V or another voltage close to 0 V, or in the 0-1 V range for coarse/fine verify or modified coarse/fine verify, or inhibiting the storage element from programming, by applying a voltage Vdd, typically a voltage from 1.5-3 V. When V_{BL} is 0 V or another low voltage (curve 1530), this voltage will be transferred to the channel area of the storage element to be programmed. In case a higher V_{BL} is applied (curve 1520), the channel will reach a higher voltage (Vdd in the ideal case). At t₃, V_{SGD} is lowered to cut off the select gate in case the bitline is at Vdd while still keeping the select gate in a conducting state for the lower V_{BL} in the 0-1 V range. At t₄, Vpass is applied to the selected word line, and to all, or almost all, of the unselected word lines of the NAND string. As a result, depending on the applied bitline voltage, V_{CH} will be boosted to a high voltage (curve 1550), when the select gate is non-conducting with Vdd at the bitline, or will stay at a low voltage (curve 1560) in the 0-1 V range which is needed for subsequent programming of the storage element.

At t₅, the high programming voltage Vpgm is applied to the selected word line, and, depending on whether the channel is boosted to a high voltage (curve 1550) or biased to a low voltage (curve 1560), the storage element will be inhibited from programming or allowed to be programmed, respectively. Actual programming of all states will mainly take place from t₆ to t₇, after Vpgm has increased to the fixed amplitude level. At t₇, Vpgm is ramped down and at t₈, Vpass is ramped down as well. Note that Vpgm can ramp up to its fixed amplitude and/or back down without stopping at Vpass. Finally, at t₉, V_{SGD} and V_{BL} are removed as well. Subsequently, one or more verify operations, essentially read operations, can be performed to verify whether the storage elements that have been selected for programming have reached their target Vt states. Additional programming pulses with increased amplitudes can be applied until all or almost all storage elements have reached their desired Vt state.

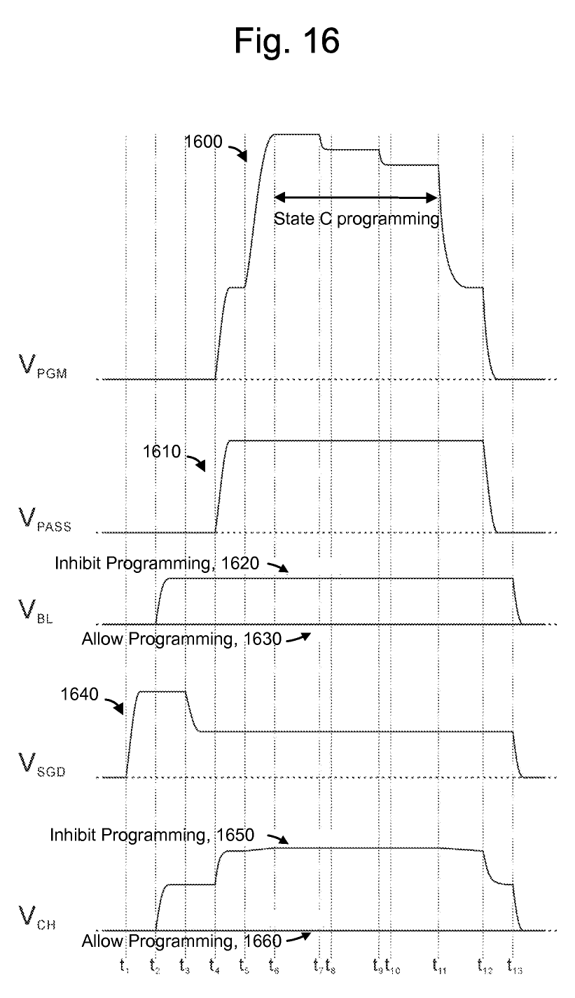

FIG. 16 depicts a timing diagram for a multi-level voltage waveform for programming non-volatile storage to a C state. Curve 1600 depicts the programming voltage waveform, Vpgm, which is applied to a word line associated with storage elements that are currently being programmed, and curve 1610 depicts Vpass which is applied to other word lines. Curve 1620 depicts the bitline voltage, V_{BL}, for a storage element which is inhibited from being programmed while Vpgm is applied, and curve 1630 depicts the bitline voltage for a storage element which is allowed to be programmed when Vpgm is applied. Curve 1640 depicts the drain side select gate voltage, V_{SGD}, of a NAND string. Curve 1650 depicts the channel voltage, V_{CH}, for the storage element when the V_{BL} 1620 is applied, and curve 1660 depicts the channel voltage for the storage element when the V_{BL} 1630 is applied. The waveforms of FIG. 16 are analogous to those of FIG. 15 except that the duration of the waveforms may be increased, in one approach. Actual programming of C state storage elements will mainly take place from t₆ to t₁₀. At t₁l, Vpgm is ramped down, and at t₁₂, Vpass is ramped down as well. Finally at t₁₃, V_{SGD} and V_{BL} are removed as well. Note that, in this and other embodiments, it is not necessary for Vpgm to stop at Vpass. Furthermore, the actual waveforms used can be slightly different for different implementations. For example, Vpgm and Vpass can ramp up and down at different times than as indicated in FIG. 15. Also, Vpgm and Vpass can be ramped up and/or down at the same time.

In one aspect of the invention, a programming waveform Vpgm that has the shape of an inverse staircase waveform is used. In the case of a multi-level storage element with an erased state and three programmed states A, B and C, for example, the Vpgm waveform includes three portions with different amplitudes. The portion with the highest amplitude can be provided first, between t₆ and t₇, followed by the portion with the next highest amplitude, between t₈ and t₉, followed by the portion with the lowest amplitude, between too and t₁l, in one possible approach. Additionally, the multi-level voltage waveform can have different forms. For example, the amplitude need not decrease during the waveform but can increase, or increase and decrease, for instance. The amplitude can be a decreasing ramp, or an increasing staircase or ramp. The ramps can be linear or non-linear. Or, the highest amplitude portion can be followed by the lowest amplitude portion and then by the intermediate amplitude portion. Various other approaches will be apparent to those skilled in the art. Successive multi-level waveforms are applied to the storage elements as in the case of the fixed amplitude waveform 1500 of FIG. 15, where the amplitude of each portion is increased in successive waveforms. Additionally, the bit line voltage is controlled so that storage elements which are to be programmed to the highest level are programmed using the entire waveform, while storage elements which are to be programmed to intermediate and lower levels are programmed using different portions of the waveform. For example, V_{BL} is set as indicated by the curve 1630 to allow programming for a storage element to be programmed to state C for the duration of the waveform 1600.

Using such a multi-level programming waveform in combination with appropriate timing for the voltages that are applied to the bit lines, it is possible to program all three or more programmed states of a multi-level memory at approximately the same time with the same number of programming loops. The highest Vt state(s) is mainly programmed during the first part of the programming waveform with the highest voltage level, while subsequent lower programmed states are programmed during latter parts of the same program waveform where the voltage level of the programming waveform is lower than the initial value that is used for the highest state. Thus, an inverse staircase type of programming waveform can be applied to the word lines, in one possible approach. Programming of the storage elements is inhibited or enabled during certain portions of the waveform in correspondence with the data that needs to be programmed to a certain storage element. After each programming waveform, all programmed states are verified and additional programming waveforms are applied until all (or almost all) storage elements are verified as being programmed to the desired state. The advantage of this approach is that all states will approximately finish programming at the same time. In contrast, when a fixed amplitude waveform is used, the lower Vt states will finish programming earlier than the higher Vt states, so additional programming waveforms are needed to program all Vt states. A further advantage, in combination with the all bit line architecture, is that having all states reach their desired programming level at approximately the same time, the negative effects of floating gate-to-floating gate coupling between storage elements on the neighboring bit lines will be reduced as neighboring storage elements will all reach their desired state, independent of whether the state is a high or low Vt state, at approximately the same time. This will result in narrower Vt distributions in comparison with full-sequence programming using fixed amplitude waveforms.

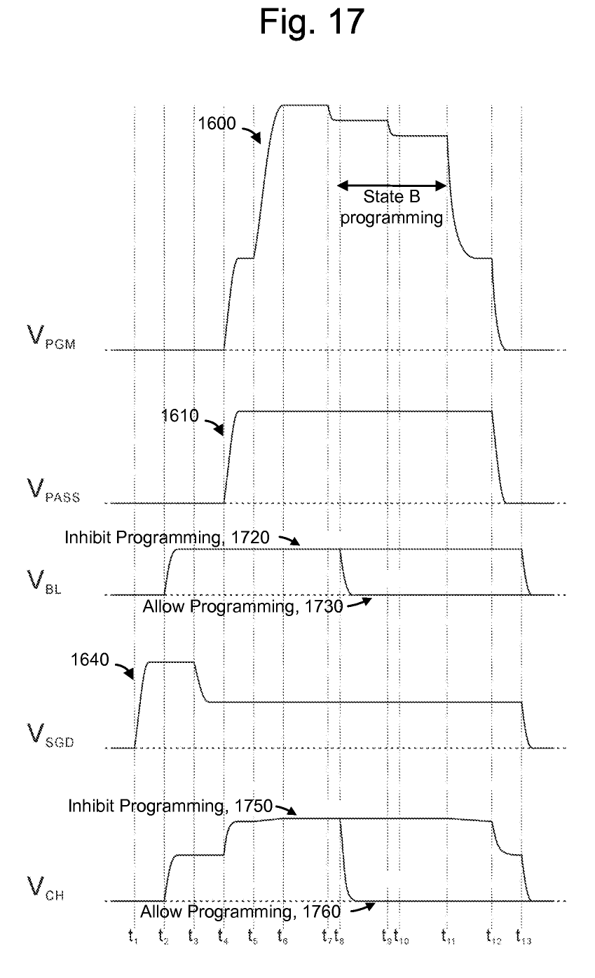

FIG. 17 depicts a timing diagram for a multi-level voltage waveform for programming non-volatile storage to a B state. The Vt for B state storage elements is lower than that for C state storage elements, so the B state storage elements only need to be programmed for a portion of the programming waveform while still achieving the goal of having all storage elements reached their respective desired states at approximately the same time.

Curve 1600 depicts the programming voltage waveform, Vpgm, which is applied to a word line associated with storage elements that are currently being programmed, and curve 1610 depicts Vpass which is applied to other word lines. Curve 1720 depicts the bitline voltage, V_{BL}, for a storage element which is inhibited from being programmed while Vpgm is applied, and curve 1730 depicts the bitline voltage for a storage element which is allowed to be programmed when Vpgm is applied. Curve 1640 depicts the drain side select gate voltage, V_{SGD}, of a NAND string. Curve 1750 depicts the channel voltage, V_{CH}, for the storage element when the V_{BL} 1720 is applied, and curve 1760 depicts the channel voltage for the storage element when the V_{BL} 1730 is applied. Actual programming will mainly take place from t₈ to

At t₁, the drain side select gate is opened by applying a relatively high voltage, e.g., 3-4.5 V. The source side select gate remains biased at 0 V. Subsequently, at t₂, a bitline voltage is applied for inhibiting the storage element from programming by applying a voltage Vdd, typically 1.5-3 V. At t₃, V_{SGD} is lowered to cut-off the select gate in case the bitline is at Vdd while still keeping the select gate in a conducting state for a lower bitline voltage in the 0-1 V range, for instance. At t₄, Vpass is applied to the selected and to all (or almost all) of the unselected word lines of the NAND string. As a result, the channel area voltage will be boosted to a high voltage. At t₅, the high programming voltage Vpgm is applied to the selected word line, however, the storage element will be inhibited from programming since the channel is still boosted. At t₇, Vpgm is lowered, and from t₈, V_{BL} is lowered to 0 V or another voltage in the 0-1 V range, for instance. As a result, from t₈ onwards, the channel voltage will change from a highly boosted state to a low voltage state and as a result, the storage element will be programmed.

Note that in case the storage element has already reached the desired B state, the channel will not be discharged at t₈. Actual programming will mainly take place from t₈ to t₁I for the B state storage element. At t₁₁, Vpgm is ramped down, and at t₁₂, Vpass is ramped down as well. Finally at t₁₃, V_{SGD} and V_{BL} are removed as well. Subsequently, one or more verify operations, essentially read operations, can be performed to verify whether the storage elements that have been selected for programming have reached their target Vt states. Additional programming waveforms with increased programming voltages can then be applied until all or almost all storage elements have reached their desired Vt state.

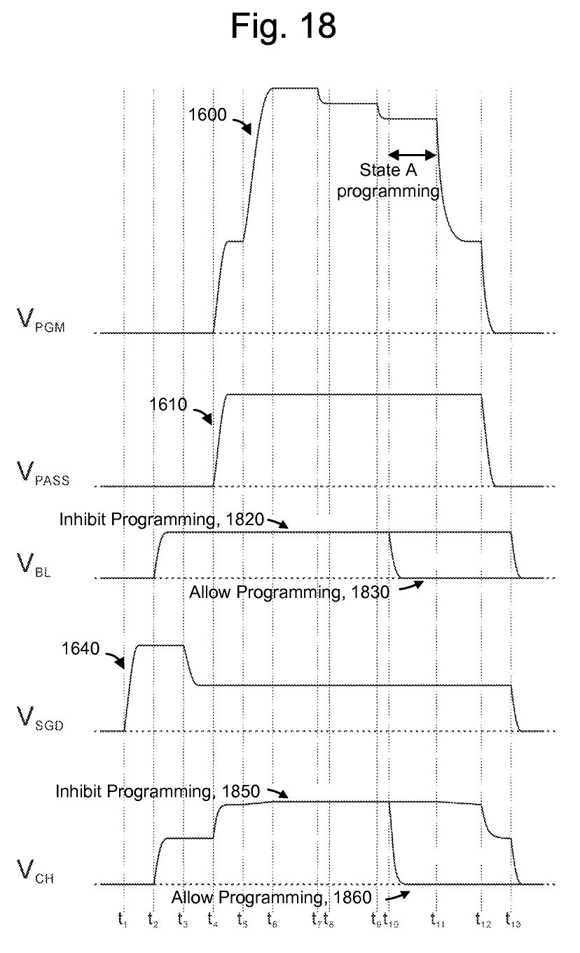

FIG. 18 depicts a timing diagram for a multi-level voltage waveform for programming non-volatile storage to an A state. The Vt for A state storage elements is lower than that for the B and C state storage elements, so the A state storage elements only need to be programmed for a smaller portion of the programming waveform while still achieving the goal of having all storage elements reached their respective desired states at approximately the same time.

Curve 1600 depicts the programming voltage waveform, Vpgm, which is applied to a word line associated with storage elements that are currently being programmed, and curve 1610 depicts Vpass which is applied to other word lines. Curve 1820 depicts the bitline voltage, V_{BL}, for a storage element which is inhibited from being programmed while Vpgm is applied, and curve 1830 depicts the bitline voltage for a storage element which is allowed to be programmed when Vpgm is applied. Curve 1640 depicts the drain side select gate voltage, V_{SGD}, of a NAND string. Curve 1850 depicts the channel voltage, V_{CH}, for the storage element when the V_{BL} 1820 is applied, and curve 1860 depicts the channel voltage for the storage element when the V_{BL} 1830 is applied. Actual programming will mainly take place from t₁₀ to t₁₁.

The waveforms are the same as provided in FIG. 17 except V_{BL} and, consequently, V_{CH} transition to a level which allows program later, at t₁₀ rather than t₈. In particular, from too onwards, V_{CH} changes from a highly boosted state to a low voltage state and as a result, programming of the storage element is allowed. Note that in case the storage element has already reached the desired A state, the channel will not be discharged at t₁₀.

Using the above techniques, storage elements that are to be programmed to the highest Vt-state, the C state, for instance, are programmed using a higher effective programming voltage and a longer programming time. Storage elements to be programmed to an intermediate state (B state) are programmed with a lower programming voltage and a shorter programming waveform duration. Storage elements to be programmed to the A-state are programmed with the lowest programming voltage and the shortest programming waveform duration. As a result, by choosing the three voltage levels of the programming waveform in an appropriate manner, it is possible for the storage elements in all three states to reach their desired final state after approximately the same number of programming loops. As a result, the total number of programming pulses will then be similar, as the number of programming pulses needed to program a single state. The number of programming waveforms can be significantly reduced in such a case. For instance, a 50% reduction in the number of programming waveforms may be possible. Another advantage in combination with ABL full-sequence operation is that, because all storage elements finish programming at approximately the same time, the influence of floating gate coupling between storage elements on the same word line is strongly reduced, resulting in narrower Vt distributions. Another potential advantage is that because the number of programming waveforms is reduced, the number of boosting events is less, and thus program disturb related to boosting will be reduced.

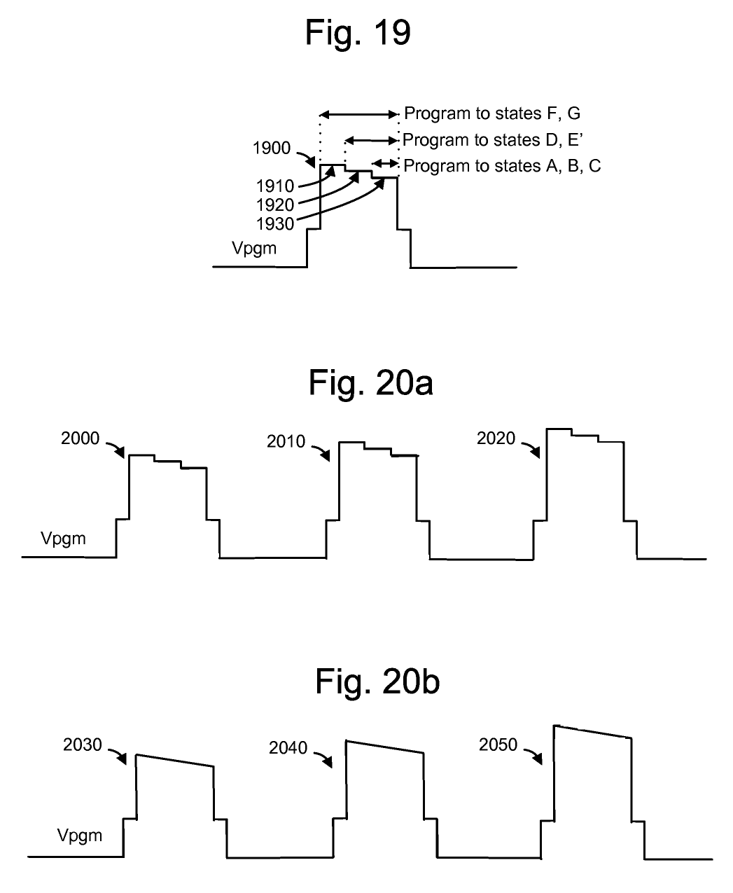

Note also that the above programming techniques can be combined with the coarse/fine verify and modified coarse/fine verify techniques. Also, the techniques can be used for more than three levels by adding more steps in the programming waveform or by programming, e.g., two or more levels that are close to another with the same portion of the programming waveform. For example, FIG. 19 depicts a timing diagram for a multi-level voltage waveform for programming non-volatile storage. In case of an eight level storage element with seven programmed states A, B, C, D, E′, F and G, where A represents the lowest Vt, G represents the highest Vt, and the other states have threshold voltages which increase successively between state A and state G, a three part waveform 1900 can be used. The waveform 1900 is a simplified representation of the waveform 1600 of FIG. 16. All three successive portions 1910, 1920 and 1930 of the waveform are used for the two highest Vt states, F and G, the second and third portions 1920 and 1930 of the waveform are used for the next two highest states, the D and E states, and the third portion 1930 of the waveform is used for the lowest states, the A, B and C states, in one possible approach. Thus, a set of storage elements to be programmed to two or more states can be allowed to be programmed, or inhibited from being programmed, during the same portion of the waveform. Moreover, depending on the memory architecture, a given storage element can transition from being inhibited to being programmed, or from being programmed to being inhibited, within a programming waveform.

FIG. 20a depicts a series of staircase amplitude voltage waveforms used for programming non-volatile storage elements. The timing diagram indicates how the storage elements are programmed by waveforms 2000, 2010 and 2020 with three portions with different amplitudes. Additionally, the amplitude of each portion of the waveform increases in successive waveforms.

FIG. 20b depicts a series of ramped amplitude voltage waveforms used for programming non-volatile storage elements. In this case, Vpgm has the shape of a decreasing ramp rather than a staircase. Moreover, the ramp can decrease linearly or nonlinearly with time. The timing diagram indicates how the storage elements are programmed by waveforms 2030, 2040 and 2050. Additionally, the amplitudes of each waveform increase in successive waveforms. The amplitude of a ramp may be identified according to an average amplitude, or a starting or ending amplitude, for instance.

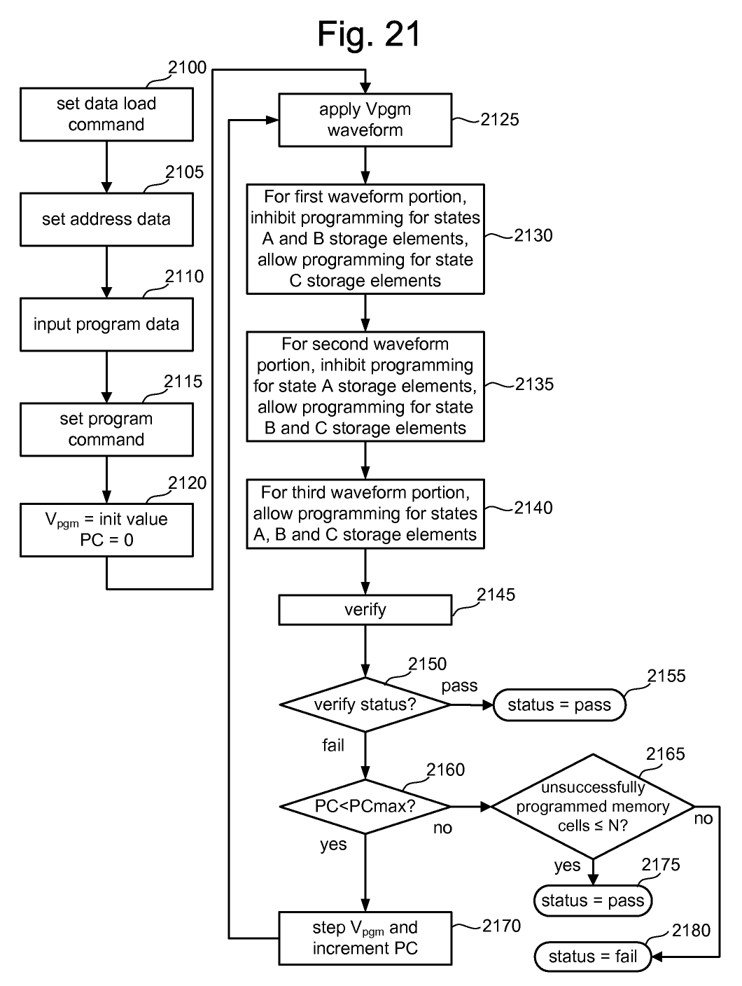

FIG. 21 is a flow chart describing one embodiment of a method for programming non-volatile memory. In one implementation, storage elements are erased (in blocks or other units) prior to programming. Storage elements are erased in one embodiment by raising the p-well to an erase voltage (e.g., 20 volts) for a sufficient period of time and grounding the word lines of a selected block while the source and bit lines are floating. Due to capacitive coupling, the unselected word lines, bit lines, select lines, and c-source are also raised to a significant fraction of the erase voltage. A strong electric field is thus applied to the tunnel oxide layers of selected storage elements and the data of the selected storage elements are erased as electrons of the floating gates are emitted to the substrate side, typically by Fowler-Nordheim tunneling mechanism. As electrons are transferred from the floating gate to the p-well region, the threshold voltage of a selected storage element is lowered. Erasing can be performed on the entire memory array, separate blocks, or another unit of storage elements.

In step 2100, a “data load” command is issued by the controller and received by control circuitry 310. In step 2105, address data designating the page address is input to decoder 314 from the controller or host. In step 2110, a page of program data for the addressed page is input to a data buffer for programming. That data is latched in the appropriate set of latches. In step 2115, a “program” command is issued by the controller to state machine 312.

Triggered by the “program” command, the data latched in step 2110 will be programmed into the selected storage elements controlled by state machine 312 using a series of programming waveforms, as discussed previously, applied to the appropriate word line. In step 2120, the program voltage Vpgm is initialized to the starting pulse (e.g., 12V or other value) and a program counter PC maintained by state machine 312 is initialized at 0. In particular, each of the multilevel portions of the programming waveform can be initialized to a respective starting level. The magnitude of the initial program pulse can be set, e.g., by properly programming a charge pump. At step 2125, the first Vpgm waveform is applied to the selected word line.

If logic “0” is stored in a particular data latch indicating that the corresponding storage element should be programmed, then the corresponding bit line is grounded for a portion of each waveform based on the state to which the storage element is to be programmed. On the other hand, if logic “1” is stored in the particular latch indicating that the corresponding storage element should remain in its current data state, then the corresponding bit line is connected to Vdd to inhibit programming.

Specifically, at step 2130, during a first portion of the voltage waveform, the storage elements on the current word line which are to be programmed to states A and B are inhibited from being programmed by raising the corresponding bit line voltages to an inhibit level, while the storage elements which are to be programmed to state C are allowed to be programmed by setting the corresponding bit line voltages at an appropriate level, e.g., 0 V. At step 2135, during a second portion of the voltage waveform, the storage elements on the current word line which are to be programmed to state A are inhibited from being programmed by raising the corresponding bit line voltages to an inhibit level, while the storage elements which are to be programmed to states B and C are allowed to be programmed by setting the corresponding bit line voltages at the appropriate level. At step 2140, during a third portion of the voltage waveform, the storage elements on the current word line which are to be programmed to states A, B or C are allowed to be programmed by setting the corresponding bit line voltages at the appropriate level. Note that the above example can be modified to encompass fewer or more than three programmed levels. For example, eight-level storage elements can be used. In this case, each programming voltage waveform can have a different amplitude. Or, the same amplitude can be provided for more than one of the states, while different amplitudes are provided for others of the states.

At step 2145, the states of the selected storage element are verified. If it is detected that the target threshold voltage of a selected storage element has reached the appropriate level, then the data stored in the corresponding data latch is changed to a logic “1.” If it is detected that the threshold voltage has not reached the appropriate level, the data stored in the corresponding data latch is not changed. In this manner, a bit line having a logic “1” stored in its corresponding data latch does not need to be programmed. When all of the data latches are storing logic “1,” the state machine knows that all selected storage elements have been programmed. At step 2150, it is checked whether all of the data latches are storing logic “1.” If so, the programming process is complete and successful because all selected memory storage elements were programmed and verified to their target states. A status of “PASS” is reported at step 2155. Optionally, a pass can be declared at step 2150 even when some of the memory elements have not yet reached their desired state. Thus, even if a certain number of storage elements can not reach the desired state, programming can stop before the maximum number of loops is reached.

If, at step 2150, it is determined that not all of the data latches are storing logic “1,” then the programming process continues. At step 2160, the program counter PC is checked against a program limit value, PCmax. One example of a program limit value is twenty, however, other values can be used in various implementations. If the program counter PC is not less than PCmax, then it is determined at step 2165 whether the number of storage elements that have not been successfully programmed is equal to or less than a predetermined number, N. If the number of unsuccessfully programmed storage elements is equal to or less than N, the programming process is flagged as passed and a status of pass is reported at step 2175. The storage elements that are not successfully programmed can be corrected using error correction during the read process. If however, the number of unsuccessfully programmed storage elements is greater than the predetermined number, the program process is flagged as failed, and a status of fail is reported at step 2180. If the program counter PC is less than PCmax, then the Vpgm level is increased by the step size and the program counter PC is incremented at step 2170. In particular, each portion of the Vpgm waveform can be increased by the step size. After step 2170, the process loops back to step 2125 to apply the next Vpgm waveform.

The flowchart depicts a single-pass programming method as can be applied for multi-level storage, such as depicted in FIG. 7. In a two-pass programming method, such as depicted in FIGS. 8 and 9a-f, multiple programming or verification steps may be used in a single iteration of the flowchart. Steps 2120-2180 may be performed for each pass of the programming operation. In a first pass, one or more program waveforms may be applied and the results thereof verified to determine if a storage element is in the appropriate intermediate state. In a second pass, one or more program waveforms may be applied and the results thereof verified to determine if the storage element is in the appropriate final state. At the end of a successful program process, the threshold voltages of the memory storage elements should be within one or more distributions of threshold voltages for programmed memory storage elements or within a distribution of threshold voltages for erased memory storage elements.

During programming, when there is a transition to only one state, such as depicted in FIG. 9a, which is the first step of a two-step programming process, the programming waveform need not include different amplitude portions. For a transition to multiple states, such as from two states to four states, depicted in FIGS. 9b and 9c, which is the second step of a two-step programming process, it is appropriate to use a programming waveform with different amplitude portions as described herein. Similarly, for the one-step programming process depicted in FIG. 7, and for each step of the two-step programming processes depicted in FIGS. 8 and 9d-f, it is appropriate to use a programming waveform with different amplitude portions as described herein.

The proposed techniques can further be extended for use with coarse/fine verify and modified coarse/fine verify techniques, for instance, by applying the appropriate bit line voltages for partially inhibiting programming during a portion of the programming waveform. Moreover, the techniques provided herein can in principal be used in all multi-level types of memories, not limited to NAND and not limited to floating gate. For example, the techniques can be used with memories that use other charge storage layers than a floating gate, such as nitride and nanocrystals. The techniques can further be used in combination with conventional NAND flash memories, and all bit line types of NAND flash memories, and is especially useful for full-sequence programming, where all states are programmed at the same time.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

1. A method for programming non-volatile storage, comprising:
applying a series of voltage waveforms to a plurality of non-volatile storage elements, each voltage waveform comprising at least a first portion followed by a second portion, the plurality of non-volatile storage elements include at least a first set of one or more non-volatile storage elements which are to be programmed to a first state and a second set of one or more non-volatile storage elements which are to be programmed to a second state;
inhibiting non-volatile storage elements in the first set from being programmed when the first portion of each voltage waveform is applied to the plurality of non-volatile storage elements; and
allowing non-volatile storage elements in the first set to be programmed when the second portion of each voltage waveform is applied to the plurality of non-volatile storage elements.

2. The method of claim 1, further comprising:
allowing non-volatile storage elements in the second set to be programmed when the first and second portions of each voltage waveform are applied to the plurality of non-volatile storage elements.

3. The method of claim 1, wherein:
the inhibiting comprises applying a voltage to bit lines associated with the non-volatile storage elements in the first set which inhibits programming therein.

4. The method of claim 1, wherein:
the allowing comprises applying a voltage to bit lines associated with the non-volatile storage elements in the first set which allows programming therein.

5. The method of claim 1, wherein each voltage waveform comprises a third portion with a third amplitude, and the plurality of non-volatile storage elements include at least a third set of one or more non-volatile storage elements which are to be programmed to a third state, the method further comprising:
inhibiting non-volatile storage elements in the first and second sets from being programmed when the third portion of each voltage waveform is applied to the plurality of non-volatile storage elements; and
allowing non-volatile storage elements in the third set to be programmed when the first, second and third portions of each voltage waveform are applied to the plurality of non-volatile storage elements.

6. The method of claim 5, wherein:
the first, second and third states correspond with first, second and third threshold voltage distributions, respectively, the first threshold voltage distribution is higher than the second threshold voltage distribution, and the third threshold voltage distribution is higher than the first threshold voltage distribution.

7. The method of claim 5, wherein:
the third portion precedes the first portion in each voltage waveform.

8. The method of claim 1, further comprising:
after applying each voltage waveform, verifying whether non-volatile storage elements in the first set have been programmed to the first state and whether non-volatile storage elements in the second set have been programmed to the second state.

9. The method of claim 8, further comprising:
locking out from further programming non-volatile storage elements in the first set which are verified to have been programmed to the first state, and non-volatile storage elements in the second set which are verified to have been programmed to the second state.

10. The method of claim 1, wherein:
each voltage waveform is applied to the plurality of non-volatile storage elements via a common word line.

11. The method of claim 1, wherein:
the first and second states correspond with first and second threshold voltage distributions, respectively, the first threshold voltage distribution is higher than the second threshold voltage distribution.

12. The method of claim 1, wherein:
each voltage waveform has an amplitude which ramps down with time.

13. The method of claim 1, wherein:
each voltage waveform has an amplitude which steps down with time.

14. The method of claim 1, wherein:
for each voltage waveform, an amplitude of the first portion is greater than an amplitude of the second portion.

15. The method of claim 1, wherein:
amplitudes of the first and second portions are increased over successive voltage waveforms.

16. The method of claim 1, wherein:
each voltage waveform starts and ends with a pass voltage whose amplitude is less than amplitudes of a remainder of the voltage waveform.

17. The method of claim 1, wherein:
the plurality of non-volatile storage elements are programmed in an all bit line architecture.

18. A method for programming non-volatile storage, comprising:
applying a series of voltage waveforms to a plurality of non-volatile storage elements, each voltage waveform comprising successive portions with different amplitudes, the plurality of non-volatile storage elements include different sets of non-volatile storage elements which are to be programmed to respective different states; and
inhibiting non-volatile storage elements in one or more of the different sets from being programmed, and allowing non-volatile storage elements in one or more others of the different sets to be programmed, according to which successive portion of the voltage waveform is being applied to the plurality of non-volatile storage elements.

19. (canceled)

20. (canceled)

21. (canceled)

22. The method of claim 18, wherein:
the different states correspond with different threshold voltage distributions.

23. (canceled)

24. (canceled)

25. The method of claim 18, wherein:
the different amplitudes of the successive portions are increased over successive voltage waveforms.

26. (canceled)

27. A method for programming non-volatile storage, comprising:
applying a series of voltage waveforms to a plurality of non-volatile storage elements, each voltage waveform comprising at least successive first and second portions with different amplitudes, the plurality of non-volatile storage elements include at least first and second sets of non-volatile storage elements;
inhibiting non-volatile storage elements in the first set from being programmed, and allowing non-volatile storage elements in the second set to be programmed, when the first portion of each voltage waveform is applied to the plurality of non-volatile storage elements; and
allowing non-volatile storage elements in the first and second sets to be programmed when the second portion of each voltage waveform is applied to the plurality of non-volatile storage elements.

28. (canceled)

29. (canceled)

30. The method of claim 27, wherein:
the first set of non-volatile storage elements are to be programmed to at least a first state, and the second set of non-volatile storage elements are to be programmed to at least second and third states, the first, second and third states corresponding with first, second and third different threshold voltage distributions, respectively.

31. The method of claim 27, wherein:
the first set of non-volatile storage elements are to be programmed to at least first and second states, and the second set of non-volatile storage elements are to be programmed to at least a third state, the first, second and third states corresponding with first, second and third different threshold voltage distributions, respectively.

32. (canceled)

33. (canceled)

34. (canceled)

35. A method for programming non-volatile storage, comprising:
applying a series of voltage waveforms to a plurality of non-volatile storage elements, each voltage waveform comprising at least successive first and second portions with different amplitudes, the plurality of non-volatile storage elements include at least first and second sets of non-volatile storage elements;
allowing non-volatile storage elements in the first and second sets to be programmed when the first portion of each voltage waveform is applied to the plurality of non-volatile storage elements; and
allowing non-volatile storage elements in the second set to be programmed and inhibiting non-volatile storage elements in the first set from being programmed when the second portion of each voltage waveform is applied to the plurality of non-volatile storage elements.

36. (canceled)

37. (canceled)

38. The method of claim 35, wherein:
the allowing non-volatile storage elements in the second set to be programmed comprises applying a voltage to bit lines associated with the non-volatile storage elements in the second set which allows programming therein.

39. (canceled)

40. (canceled)

41. (canceled)

42. (canceled)

43. (canceled)

44. A non-volatile storage system, comprising:
a plurality of non-volatile storage elements;
one or more circuits for programming the plurality of non-volatile storage elements, the one or more circuits (a) applying a series of voltage waveforms to the plurality of non-volatile storage elements, each voltage waveform comprising at least a first portion followed by a second portion, the plurality of non-volatile storage elements include at least a first set of one or more non-volatile storage elements which are to be programmed to a first state and a second set of one or more non-volatile storage elements which are to be programmed to a second state, (b) inhibiting non-volatile storage elements in the first set from being programmed when the first portion of each voltage waveform is applied to the plurality of non-volatile storage elements, and (c) allowing non-volatile storage elements in the first set to be programmed when the second portion of each voltage waveform is applied to the plurality of non-volatile storage elements.

45. The non-volatile storage system of claim 44, wherein:
the one or more circuits allow non-volatile storage elements in the second set to be programmed when the first and second portions of each voltage waveform are applied to the plurality of non-volatile storage elements.

46. The non-volatile storage system of claim 44, wherein:
the inhibiting comprises applying a voltage to bit lines associated with the non-volatile storage elements in the first set which inhibits programming therein.

47. The non-volatile storage system of claim 44, wherein:
the allowing comprises applying a voltage to bit lines associated with the non-volatile storage elements in the first set which allows programming therein.

48. The non-volatile storage system of claim 44, wherein:
each voltage waveform comprises a third portion with a third amplitude, and the plurality of non- volatile storage elements include at least a third set of one or more non-volatile storage elements which are to be programmed to a third state, and the one or more circuits inhibit non-volatile storage elements in the first and second sets from being programmed when the third portion of each voltage waveform is applied to the plurality of non-volatile storage elements, and allow non-volatile storage elements in the third set to be programmed when the first, second and third portions of each voltage waveform are applied to the plurality of non-volatile storage elements.

49. The non-volatile storage system of claim 48, wherein:
the first, second and third states correspond with first, second and third threshold voltage distributions, respectively, the first threshold voltage distribution is higher than the second threshold voltage distribution, and the third threshold voltage distribution is higher than the first threshold voltage distribution.

50. The non-volatile storage system of claim 48, wherein:
the third portion precedes the first portion in each voltage waveform.

51. The non-volatile storage system of claim 44, wherein:
after applying each voltage waveform, the one or more circuits verify whether non-volatile storage elements in the first set have been programmed to the first state and whether non-volatile storage elements in the second set have been programmed to the second state.

52. The non-volatile storage system of claim 51, wherein:
the one or more circuits lockout from further programming non-volatile storage elements in the first set which are verified to have been programmed to the first state, and non-volatile storage elements in the second set which are verified to have been programmed to the second state.

53. The non-volatile storage system of claim 44, wherein:
each voltage waveform is applied to the plurality of non-volatile storage elements via a common word line.

54. The non-volatile storage system of claim 44, wherein:
the first and second states correspond with first and second threshold voltage distributions, respectively, the first threshold voltage distribution is higher than the second threshold voltage distribution.

55. The non-volatile storage system of claim 44, wherein:
each voltage waveform has an amplitude which ramps down with time.

56. The non-volatile storage system of claim 44, wherein:
each voltage waveform has an amplitude which steps down with time.

57. The non-volatile storage system of claim 44, wherein:
for each voltage waveform, an amplitude of the first portion is greater than an amplitude of the second portion.

58. The non-volatile storage system of claim 44, wherein:
amplitudes of the first and second portions are increased over successive voltage waveforms.

59. The non-volatile storage system of claim 44, wherein:
each voltage waveform starts and ends with a pass voltage whose amplitude is less than amplitudes of a remainder of the voltage waveform.

60. The non-volatile storage system of claim 44, wherein:
the plurality of non-volatile storage elements are programmed in an all bit line architecture.

61. A non-volatile storage system, comprising:
a plurality of non-volatile storage elements;
one or more circuits for programming the plurality of non-volatile storage elements, the one or more circuits (a) applying a series of voltage waveforms to the plurality of non-volatile storage elements, each voltage waveform comprising successive portions with different amplitudes, the plurality of non-volatile storage elements include different sets of non-volatile storage elements which are to be programmed to respective different states, and (b) inhibiting non-volatile storage elements in one or more of the different sets from being programmed, and allowing non-volatile storage elements in one or more others of the different sets to be programmed, according to which successive portion of the voltage waveform is being applied to the plurality of non-volatile storage elements.

62. The non-volatile storage system of claim 61, wherein:
the different states correspond with different threshold voltage distributions.

63. The non-volatile storage system of claim 61, wherein:
the different amplitudes of the successive portions are increased over successive voltage waveforms.

64. A non-volatile storage system for programming non-volatile storage, comprising:
a plurality of non-volatile storage elements;
one or more circuits for programming the plurality of non-volatile storage elements, the one or more circuits (a) applying a series of voltage waveforms to the plurality of non-volatile storage elements, each voltage waveform comprising at least successive first and second portions with different amplitudes, the plurality of non-volatile storage elements include at least first and second sets of non-volatile storage elements, (b) inhibiting non-volatile storage elements in the first set from being programmed, and allowing non-volatile storage elements in the second set to be programmed, when the first portion of each voltage waveform is applied to the plurality of non-volatile storage elements, and (c) allowing non-volatile storage elements in the first and second sets to be programmed when the second portion of each voltage waveform is applied to the plurality of non-volatile storage elements.

65. The non-volatile storage system of claim 64, wherein:
the first set of non-volatile storage elements are to be programmed to at least a first state, and the second set of non-volatile storage elements are to be programmed to at least second and third states, the first, second and third states corresponding with first, second and third different threshold voltage distributions, respectively.

66. The non-volatile storage system of claim 64, wherein:
the first set of non-volatile storage elements are to be programmed to at least first and second states, and the second set of non-volatile storage elements are to be programmed to at least a third state, the first, second and third states corresponding with first, second and third different threshold voltage distributions, respectively.

67. A non-volatile storage system for programming non-volatile storage, comprising:
a plurality of non-volatile storage elements;
one or more circuits for programming the plurality of non-volatile storage elements, the one or more circuits (a) applying a series of voltage waveforms to the plurality of non-volatile storage elements, each voltage waveform comprising at least successive first and second portions with different amplitudes, the plurality of non-volatile storage elements include at least first and second sets of non-volatile storage elements, (b) allowing non-volatile storage elements in the first and second sets to be programmed when the first portion of each voltage waveform is applied to the plurality of non-volatile storage elements, and (c) allowing non-volatile storage elements in the second set to be programmed and inhibiting non-volatile storage elements in the first set from being programmed when the second portion of each voltage waveform is applied to the plurality of non-volatile storage elements.

68. The non-volatile storage system of claim 67, wherein:
the allowing non-volatile storage elements in the second set to be programmed comprises applying a voltage to bit lines associated with the non-volatile storage elements in the second set which allows programming therein.
